(19) United States
(12) Patent Application Publication
(10) Pub. No.: US 2016/0351499 A1
(43) Pub. Date: Dec. 1, 2016

(54) SEMICONDUCTOR DEVICE AND ELECTRONIC DEVICE

(71) Applicant: FUJITSU LIMITED, Kawasaki-shi (JP)

(72) Inventor: Hideki Kitada, Atsugi (JP)

(73) Assignee: FUJITSU LIMITED, Kawasaki-shi (JP)

(21) Appl. No.: 15/157,810

(22) Filed: May 18, 2016

(30) Foreign Application Priority Data
May 25, 2015 (JP) 2015-105310

(51) Int. Cl. H01L 23/528; H01L 21/768; H01L 23/00; H01L 23/522; H01L 25/065

(52) U.S. Cl. CPC H01L 23/5283; H01L 23/5226; H01L 25/0657; H01L 24/06; H01L 21/76877; H01L 21/76843; H01L 2224/0401

(57) ABSTRACT

A semiconductor device includes a semiconductor substrate, a through hole via which pierces the semiconductor substrate, and a wiring layer (multilayer wirings) disposed under the semiconductor substrate and including plural layers of a group of lands disposed under the through hole via. The group of lands includes a land in a first layer which is disposed on an under surface of the through hole via and which is equal in external size to or smaller in external size than the through hole via in planar view and a land in a second layer which is disposed under the land in the first layer and which is larger in external size than the land in the first layer in the planar view. The lands in the first and second layers suppress concentration of stress transmitted by pop-ups from the through hole via to the group of lands and prevent cracks.

### CROSS-REFERENCE TO RELATED APPLICATION

This application is based upon and claims the benefit of priority of the prior Japanese Patent Application No. 2015-105310, filed on May 25, 2015, the entire contents of which are incorporated herein by reference.

### FIELD

The embodiments discussed herein are related to a semiconductor device and an electronic device.

### BACKGROUND

The technique of forming a through hole via (referred to as a through silicon vis (TSV) or the like) which pierces a semiconductor substrate made of silicon (Si) or the like by the use of a metal material, such as copper (Cu), is known. For example, a semiconductor device having the following structure is proposed as a semiconductor device including such a through hole via. In multilayer wirings formed over a semiconductor substrate on which circuit elements, such as transistors, are formed, a wiring which is larger in external size than a through hole via is formed over the through hole via in the semiconductor substrate and an upper-layer wiring is formed over that wiring.

See, for example, Japanese Laid-open Patent Publication No. 2013-247273.

With a semiconductor device using a semiconductor substrate in which a through hole via is formed, the thermal expansion coefficient of a metal material used for forming the through hole via is greater than that of a material for the semiconductor substrate. As a result, the following phenomenon may occur. An end portion of the through hole via projects outward at heating time due to the difference in thermal expansion coefficient between them. This phenomenon is what is called a pop-up. A crack may appear in multilayer wirings formed over the surface of the semiconductor substrate due to the displacement of the end portion of the through hole via caused by the pop-up or stress created near the end portion of the through hole via as a result of the pop-up. A crack in the multilayer wirings may lead to deterioration in the performance or quality, such as leakage failure or embrittlement, of the semiconductor device.

### SUMMARY

According to an aspect, there is provided a semiconductor device including a semiconductor substrate, a through hole via which pierces the semiconductor substrate, and multilayer wirings disposed under the semiconductor substrate and including plural layers of a group of lands disposed under the through hole via, the group of lands including a first land in a first layer from a through hole via side which is disposed on an under surface of the through hole via and which is equal in external size to or smaller in external size than the through hole via in planar view and a second land in a second layer from the through hole via side which is disposed under the first land and which is larger in external size than the first land in the planar view.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 illustrates an example of a three-dimensional stacked device in which a three-dimensional stacking technique is employed;

FIG. 2 illustrates an example of a chip used in a three-dimensional stacked device;

FIG. 3 illustrates an example of a state at the time of the expansion of a through hole via;

FIGS. 4A and 4B indicate an example of the relationship between an external diameter and a displacement amount of a through hole via;

FIG. 5 is a view for describing an example of a crack which appears near a through hole via;

FIG. 6 is a view for describing stress created near a through hole via;

FIG. 7 indicates an example of the distribution of stress created near a through hole via;

FIG. 8 is a view for describing stress created near a through hole via at the time of forming a group of lands in another shape;

FIG. 9 indicates an example of the distribution of stress created near the through hole via at the time of forming the group of lands in another shape;

FIG. 10 illustrates an example of a chip according to a first embodiment (part 1);

FIG. 11 illustrates the example of the chip according to the first embodiment (part 2);

FIG. 12 is a view for describing stress created near a through hole via in the chip according to the first embodiment;

FIG. 13 illustrates another example of the chip according to the first embodiment;

FIG. 14 illustrates an example of a chip according to a second embodiment;

FIG. 15 illustrates example 1 of a land in the second embodiment;

FIG. 16 illustrates example 2 of a land in the second embodiment;

FIG. 17 illustrates an example of connection of lands by vias in the second embodiment;

FIG. 18 is a view for describing stress created near a through hole via in the chip according to the second embodiment;

FIG. 19 indicates an example of the distribution of stress created near a through hole via in the chip according to the second embodiment;

FIG. 20 illustrates another example of the chip according to the second embodiment;

FIG. 21 illustrates an example of a chip according to a third embodiment;

FIG. 22 illustrates an example of a chip according to a fourth embodiment;

FIG. 23 illustrates an example of a chip according to a fifth embodiment;

FIG. 24 illustrates an example of a chip fabrication method according to a sixth embodiment (part 1);

FIG. 25 illustrates the example of the chip fabrication method according to the sixth embodiment (part 2);

FIG. 26 illustrates the example of the chip fabrication method according to the sixth embodiment (part 3);

FIG. 27 illustrates the example of the chip fabrication method according to the sixth embodiment (part 4); and

FIG. 28 illustrates an example of a three-dimensional stacked device fabrication method according to the sixth embodiment.

### DESCRIPTION OF EMBODIMENTS

First a device using a through hole via, such as a TSV, will be described.

In recent years there has been a growing demand for multi-chip modules (electronic devices) in which a chip group of electronic elements is mounted on a single board (such as a circuit board or a chip). With multi-chip modules a chip group including a semiconductor chip, a sensor chip, and a memory chip which are, for example, integrated circuits (ICs) are mounted together in a single package. Accordingly, it is comparatively easy to miniaturize products or raise the integration density of products.

A structure in which a chip group or a package group including chips (chip groups) are integrated two-dimensionally or a structure in which a chip group or a package group are integrated three-dimensionally by stacking is known as a structure of a multi-chip module.

With a three-dimensional stacked device in which a chip group are integrated by stacking, the method of electrically connecting chip groups or package groups by wire bonding, the method of electrically connecting chip groups or package groups by through hole vias formed in them, or the like is known.

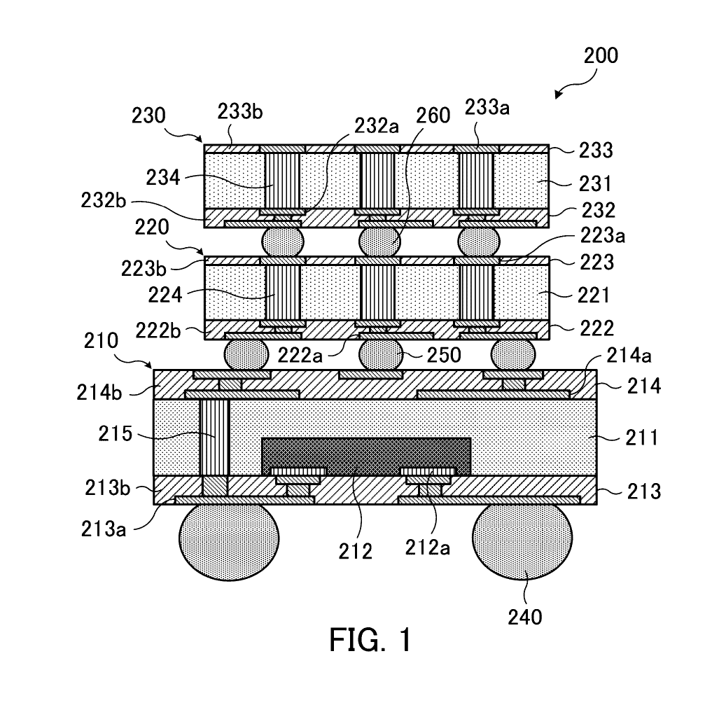

FIG. 1 illustrates an example of a multi-chip module (three-dimensional stacked device) in which a three-dimensional stacking technique is employed. FIG. 1 is a fragmentary schematic sectional view of an example of a three-dimensional stacked device.

FIG. 1 illustrates a three-dimensional stacked device 200 in which three chips 210, 220, and 230 are stacked.

The chip 210 includes a resin layer 211, a semiconductor chip 212 embedded in the resin layer 211, and a wiring layer 213 and a wiring layer (rewiring layer) 214 formed over the front surface and back surface, respectively, of the resin layer 211. That is to say, the chip 210 is what is called a pseudo system on chip (SOC). The chip 210 further includes a through hole via 215 which pierces the resin layer 211 and which electrically connects the wiring layer 213 and the wiring layer 214 formed over the front surface and back surface, respectively, of the resin layer 211.

A resin material, such as epoxy resin, is used for forming the resin layer 211. The resin material may contain insulating filler such as silica. The semiconductor chip 212 is embedded in the resin layer 211 so that a terminal 212a will be exposed.

The semiconductor chip 212 is, for example, large scale integration (LSI) including circuit elements such as transistors which are, for example, logic transistors. In addition to the semiconductor chip 212, at least one semiconductor chip whose kind is the same as or different from that of the semiconductor chip 212 or at least one chip part, such as a chip capacitor, may be included in the resin layer 211.

The wiring layer 213 formed on the side of the surface of the semiconductor chip 212 on which the terminal 212a is exposed includes a conductor portion (such as a wiring or a via) 213a electrically connected to the terminal 212a and one end of the through hole via 215 and an insulating portion 213b which covers a determined part of the conductor portion 213a. The wiring layer 214 formed on the side of the opposite surface of the semiconductor chip 212 includes a conductor portion (such as a wiring or a via) 214a electrically connected to the other end of the through hole via 215 and an insulating portion 214b which covers a determined part of the conductor portion 214a. The conductor portion 213a and the conductor portion 214a are formed by the use of a conductor material such as Cu. The insulating portion 213b and the insulating portion 214b are formed by the use of an insulating material such as polyimide.

The through hole via 215 which pierces the resin layer 211 and which electrically connects the wiring layer 213 and the wiring layer 214 is formed by the use of a conductor material such as polysilicon, tungsten (W), or Cu.

The chip 220 is a semiconductor chip and includes a semiconductor substrate 221, which is a Si substrate or the like, and a wiring layer 222 and a wiring layer 223 formed over the front surface and back surface, respectively, of the semiconductor substrate 221. Circuit elements (not illustrated), such as transistors, are formed on the semiconductor substrate 221. The chip 220 further includes a through hole via 224 which pierces the semiconductor substrate 221 and which electrically connects the wiring layer 222 and the wiring layer 223. The through hole via 224 is formed by the use of a conductor material such as polysilicon, W, or Cu. A side edge portion of the through hole via 224 is, for example, an insulating film (not illustrated). In that case, a conductor material, such as Cu, is used inside the insulating film.

The wiring layer 222 of the chip 220 includes a conductor portion (such as a wiring or a via) 222a electrically connected to the through hole via 224 and an insulating portion 222b which covers a determined part of the conductor portion 222a. The wiring layer 223 of the chip 220 includes a conductor portion (such as a wiring or a via) 223a electrically connected to the through hole via 224 and an insulating portion 223b which covers a determined part of the conductor portion 223a. The conductor portion 222a and the conductor portion 223a are formed by the use of a conductor material such as Cu. The insulating portion 222b and the insulating portion 223b are formed by the use of an insulating material such as silicon oxide (SiO) or silicon nitride (SiN).

Similarly, the chip 230 is a semiconductor chip and includes a semiconductor substrate 231, which is a Si substrate or the like, and a wiring layer 232 and a wiring layer 233 formed over the front surface and back surface, respectively, of the semiconductor substrate 231. Circuit elements (not illustrated), such as transistors, are formed on the semiconductor substrate 231. The chip 230 further includes a through hole via 234 which pierces the semiconductor substrate 231 and which electrically connects the wiring layer 232 and the wiring layer 233. The through hole via 234 is formed by the use of a conductor material such as polysilicon, W, or Cu. A side edge portion of the through hole via 234 is, for example, an insulating film (not illustrated). In that case, a conductor material, such as Cu, is used inside the insulating film.

The wiring layer 232 of the chip 230 includes a conductor portion (such as a wiring or a via) 232a electrically connected to the through hole via 234 and an insulating portion 232b which covers a determined part of the conductor portion 232a. The wiring layer 233 of the chip 230 includes a conductor portion (such as a wiring or a via) 233a electrically connected to the through hole via 234 and an insulating portion 233b which covers a determined part of the conductor portion 233a. The conductor portion 232a and the conductor portion 233a are formed by the use of a conductor material such as Cu. The insulating portion 232b and the insulating portion 233b are formed by the use of an insulating material such as SiO.

The wiring layer 223 (its conductor portion 223a) of the chip 220 and the wiring layer 232 (its conductor portion 232a) of the chip 230 are electrically connected via a bump 260. The wiring layer 222 (its conductor portion 222a) of the chip 220 and the wiring layer 214 (its conductor portion 214a) of the chip 210 are electrically connected via a bump 250. A bump 240 is electrically connected to the wiring layer 213 (its conductor portion 213a) of the chip 210. The bump 240 is used as an external connection terminal of the three-dimensional stacked device 200.

For example, a semiconductor chip, such as LSI or a memory chip, is used as the chip 220 or the chip 230.

For example, the three-dimensional stacked device 200 is obtained by stacking the chip 220 and the chip 230, which are memory chips, over the chip 210 (pseudo-SoC) containing the semiconductor chip 212 including circuit elements such as logic transistors. With this three-dimensional stacked device 200 the adoption of the method of electrically connecting the chip 210, the chip 220, and the chip 230 in the above way by the use of the through hole via 215, the through hole via 224, and the through hole via 234 is advantageous in, for example, signal transmission between the memory chips and the logic transistors. That is to say, signal transmission line length (bus length) is short compared with the method of electrically connecting the chip 220 and the chip 230 to the chip 210 by wire bonding. As a result, a high-speed and high bandwidth bus is realized or a reduction in power consumption is realized. Furthermore, with a device such as a mobile terminal, the size of a package is reduced. As a result, for example, a battery area is expanded.

In the three-dimensional stacked device 200 illustrated in FIG. 1, the number of layers in which the chip group are stacked is three. However, the number of layers is not limited to three. Furthermore, in addition to a semiconductor chip such as a memory chip, a relay substrate, such as a Si interposer, may be used in a layer between the undermost layer and the uppermost layer. In addition, a case where a chip group are stacked over a pseudo-SoC is taken as an example. However, a three-dimensional stacked device may be obtained by stacking a chip group over a circuit board such as a printed circuit board on which a determined conductor pattern is formed.

As stated above, in order to electrically connect wiring layers formed over the front surface and back surface of a chip in a three-dimensional stacked device, a through hole via is formed so as to pierce the front surface and back surface.

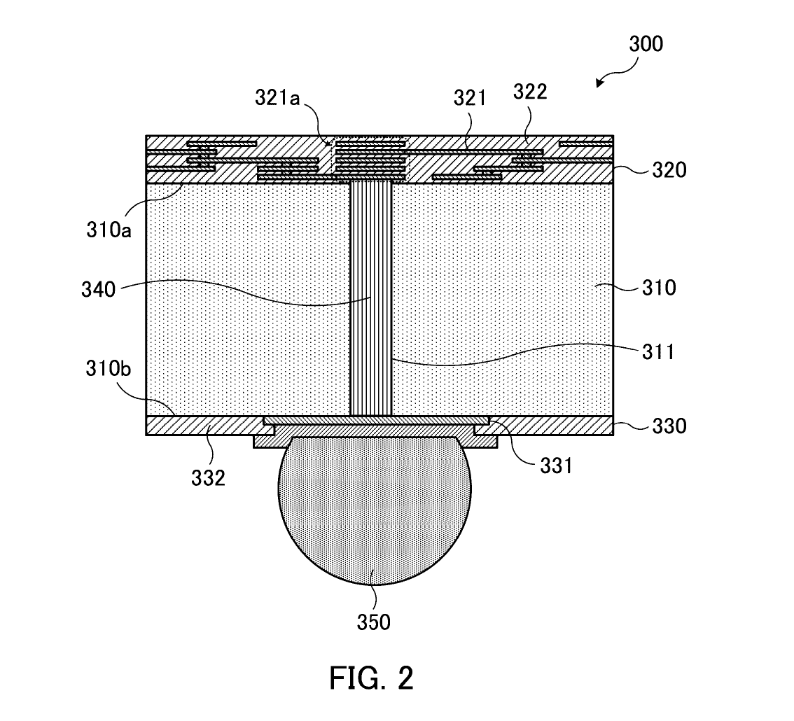

FIG. 2 illustrates an example of a chip used in a three-dimensional stacked device. FIG. 2 is a fragmentary schematic sectional view of an example of a chip.

As illustrated in FIG. 2, a through hole via 340 is formed in a chip 300 used in a three-dimensional stacked device. The through hole via 340 pierces a semiconductor substrate 310, such as a Si substrate, and electrically connects a wiring layer 320 (multilayer wirings) formed on a front surface 310a side of the semiconductor substrate 310 and a wiring layer 330 (back end of line (BEOL)) formed on a back surface 310b side of the semiconductor substrate 310.

Circuit elements, such as transistors, are formed on the front surface (active surface) 310a of the semiconductor substrate 310. The through hole via 340 which pierces the semiconductor substrate 310 is formed by the use of a conductor material such as polysilicon, W, or Cu. A side edge portion of the through hole via 340 is, for example, an inorganic or organic insulating film (not illustrated). In that case, a conductor material, such as Cu, is used inside the insulating film. Direct contact of the semiconductor substrate 310 with a conductor material used for forming the through hole via 340 is avoided by the use of the insulating film.

The wiring layer 320 (active layer) formed on the front surface 310a side of the semiconductor substrate 310 includes a conductor portion 321 (such as a wiring or a via) and an insulating portion 322. The conductor portion 321 is formed by the use of a conductor material such as Cu. The insulating portion 322 is formed by the use of an insulating material such as SiO. A land is formed in a part of the wiring of the conductor portion 321 to which a via is connected. As illustrated in FIG. 2, for example, the conductor portion 321 of the wiring layer 320 includes plural layers (five layers, in this example) of a group of lands 321a formed over one end of the through hole via 340. For example, the group of lands 321a is larger in external size than the through hole via 340 in planar view and is disposed so as to overhang the through hole via 340.

The wiring layer 330 formed on the back surface 310b side of the semiconductor substrate 310 includes a conductor portion 331 (such as a wiring or an under bump metal (UBM)) and an insulating portion 332. The conductor portion 331 is formed by the use of a conductor material such as Cu. The insulating portion 332 is formed by the use of an inorganic or organic insulating material. The conductor portion 331 is formed under the other end of the through hole via 340 and is electrically connected to the through hole via 340. A bump 350 is formed over the conductor portion 331. The bump 350 is used as an external connection terminal of the chip 300.

The above chip 300 including the through hole via 340 is formed, for example, in the following way.

First the wiring layer 320 is formed over the front surface 310a of the semiconductor substrate 310 on which transistors and the like are formed. In order to form the wiring layer 320, a photolithography technique, an etching technique, an insulating film and conductive film formation technique, and the like are used.

Next, a through hole 311 is made from the back surface 310b side of the semiconductor substrate 310 at a position at which the through hole via 340 is to be formed. The through hole 311 pierces the semiconductor substrate 310 and reaches the group of lands 321a of the wiring layer 320. If a Si substrate is used as the semiconductor substrate 310, then the through hole 311 is made, for example, by performing dry etching by the use of sulfur hexafluoride (SF₆)-based gas.

After that, the through hole via 340 is formed in the through hole 311. For example, an insulating film is formed on the inner wall of the through hole 311. The through hole 311 is filled with a conductor material by copper electroplating. As a result, the through hole via 340 is formed. After the through hole via 340 is formed, heat treatment is performed at a determined temperature for, for example, stabilization (crystallization, crystal grain growth, unnecessary component removal, or the like) of the conductor material.

After the through hole via 340 is formed, the wiring layer 330 is formed over the back surface 310b of the semiconductor substrate 310. The wiring layer 330 includes the conductor portion 331 electrically connected to the through hole via 340. The bump 350 is formed over the conductor portion 331.

The above chip 300 is formed in this way.

Alternatively, the chip 300 is formed in the following way.

First a through hole 311 which reaches the inside of the semiconductor substrate 310 is made on a front surface 310a side of the semiconductor substrate 310 on which transistors and the like are formed. A via (which is to become the above through hole via 340) is formed in the through hole 311. Heat treatment is performed at a determined temperature and then the wiring layer 320 is formed on the front surface 310a side of the semiconductor substrate 310. After that, a back surface side of the semiconductor substrate 310 is ground by a back grinding method. As a result, the via formed in the semiconductor substrate 310 gets exposed and the through hole via 340 is formed. The wiring layer 330 including the conductor portion 331 is formed on the back surface 310b side of the semiconductor substrate 310 on which an end of the through hole via 340 is exposed. The bump 350 is formed over the conductor portion 331. As a result, the chip 300 is formed.

By the way, with the above chip 300 a failure may occur due to the through hole via 340. This problem will now be described.

The chip 300 in which a Si substrate is used as the semiconductor substrate 310 and in which copper is used as a conductor material for forming the through hole via 340 is taken as an example. In this case, the thermal expansion coefficient of silicon is 2.3 ppm/K and the thermal expansion coefficient of copper is 16.6 ppm/K. That is to say, there is a comparatively great difference in thermal expansion coefficient between the semiconductor substrate 310 and the through hole via 340.

After the through hole via 340 is formed in the process for forming the chip 300, heat is applied when copper with which the through hole 311 is filled is stabilized or when a film is formed. The thermal expansion coefficient of copper in the through hole via 340 is higher than that of silicon in the semiconductor substrate 310. Accordingly, at this time copper in the through hole via 340 tends to greatly expand, compared with silicon in the semiconductor substrate 310.

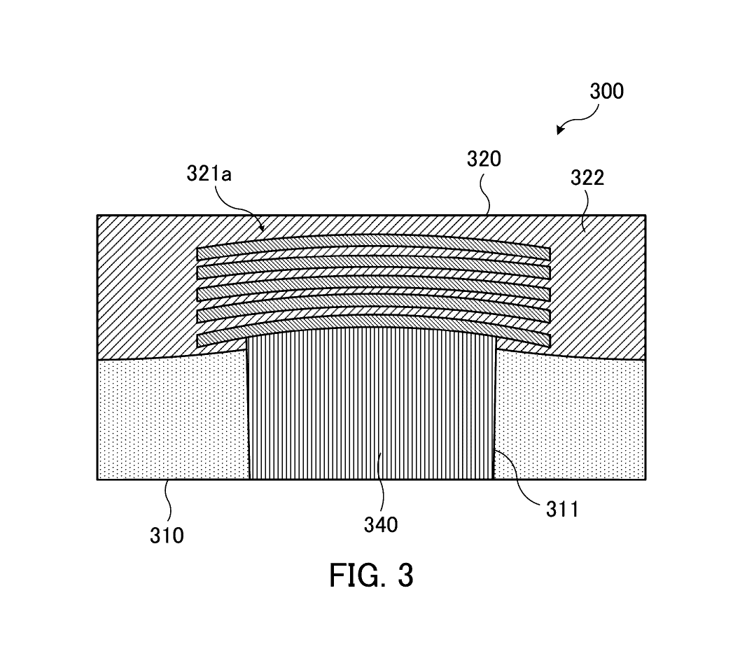

FIG. 3 illustrates an example of a state at the time of the expansion of the through hole via. FIG. 3 is a schematic sectional view of an end portion of the through hole via right over which the group of lands is formed and its peripheral portions.

As illustrated in FIG. 3, when heat is applied to the through hole via 340 formed in the semiconductor substrate 310, the through hole via 340 may expand due to the difference in thermal expansion coefficient between the semiconductor substrate 310 and the through hole via 340 so as to project to the outside of the through hole 311. Furthermore, crystal grain growth of copper of the through hole via 340 may take place at heating time. As illustrated in FIG. 3, the through hole via 340 may expand, due to the crystal grain growth of copper of the through hole via 340 and the above difference in thermal expansion coefficient between the through hole via 340 and the semiconductor substrate 310, so as to project to the outside of the through hole 311.

The phenomenon of the through hole via 340 expanding in this way so as to project from the through hole 311 in the semiconductor substrate 310 is referred to as a pop-up (or pumping). As the external diameter (diameter) of the through hole via 340 increases and the volume of the through hole via 340 increases, a pop-up tends to occur more remarkably.

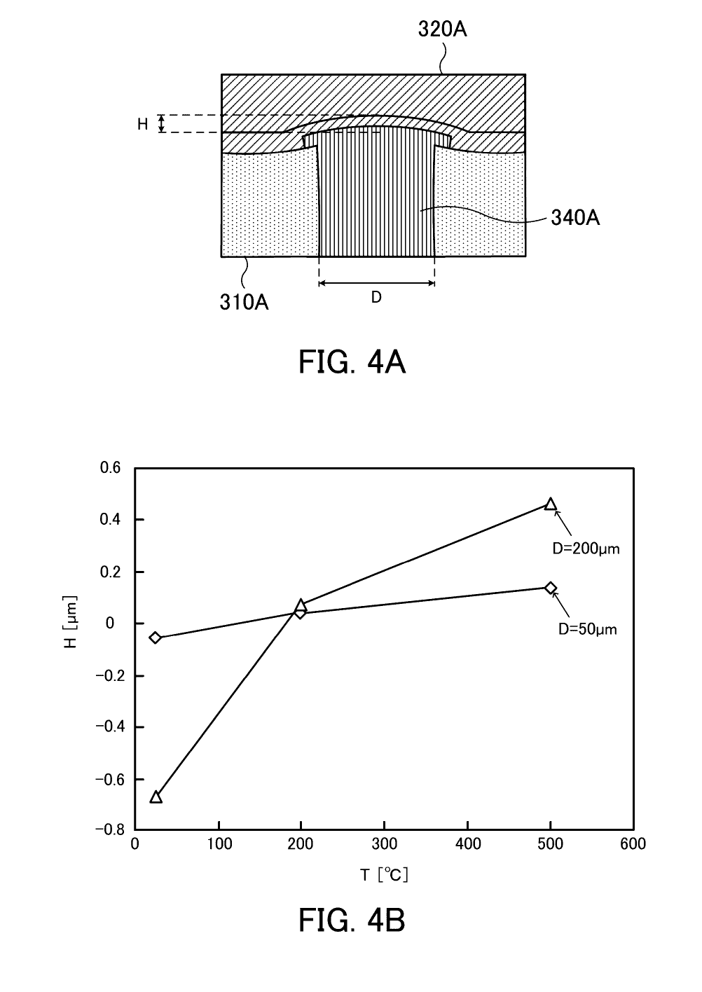

FIGS. 4A and 4B indicate an example of the relationship between an external diameter and a displacement amount of a through hole via. FIG. 4A is a schematic sectional view of an end portion of a through hole via and its peripheral portions. FIG. 4B indicates an example of calculation of a displacement amount of an upper layer portion obtained as a result of the expansion of a through hole via.

A model illustrated in FIG. 4A has the following structure. A Cu through hole via 340A is formed in a Si substrate 310A and reaches an active layer (wiring layer) 320A. This model is used for calculating a displacement amount. The thickness of the Si substrate 310A is set to 200 μm. The external diameter D (μm) of the Cu through hole via 340A is set to 200 μm and 50 μm. Furthermore, the thermal expansion coefficient of the Si substrate 310A is set to 2.3 ppm/K. The thermal expansion coefficient of the Cu through hole via 340A is set to 16.6 ppm/K. It is assumed that the active layer 320A is an interlayer insulating film, and its thermal expansion coefficient is set to 130 ppm/K which is a typical value.

Copper is recrystallized at 250° C. and stress is zero. A displacement amount H of the active layer 320A indicated in FIG. 4A is estimated from a residual stress value, a stress value at 25° C., a stress value at 200° C. (at which heating is performed in the chip formation process), and a stress value at 500° C. (at which the heat treatment is performed after the formation of the through hole via). FIG. 4B indicates an example of the relationship between temperature T (° C.) and a displacement amount H (μm) of the active layer 320A obtained for the Cu through hole via 340A having each external diameter D (200 μm or 50 μm).

As can be seen from FIG. 4B, when temperature T is 500° C., a displacement amount H is about 0.1 μm for the Cu through hole via 340A whose external diameter D is 50 μm. That is to say, the expansion of the Cu through hole via 340A causes displacement of the active layer 320A. When temperature T is 500° C., a displacement amount H is about 0.4 μm for the Cu through hole via 340A whose external diameter D is 200 μm. Compared with the Cu through hole via 340A whose external diameter D is 50 μm, the expansion of the Cu through hole via 340A whose external diameter D is 200 μm causes large displacement of the active layer 320A.

As the external diameter D of the Cu through hole via 340A increases and the volume of the Cu through hole via 340A increases, displacement of the active layer 320A, or a pop-up of the Cu through hole via 340A tends to occur more remarkably.

From this point of view, in order to suppress a pop-up (displacement of the wiring layer (active layer) 320) in the chip 300 illustrated in FIGS. 2 and 3, it may be desirable to form a through hole via 340 having a narrow external diameter, or a thin through hole via 340 in the semiconductor substrate 310. However, as the through hole via 340 becomes thinner, an aspect ratio rises. This increases the possibility that a problem about production will arise. For example, it is difficult to make the through hole 311 in the semiconductor substrate 310 or to fill the through hole 311 with a conductor material. Furthermore, this increases the possibility that a structural problem will arise. For example, as the through hole via 340 becomes thinner, internal stress becomes stronger. In addition, the resistance increases because the plane size (area of contact with the conductor portion 321 of the wiring layer 320) decreases.

When a pop-up of the through hole via 340 occurs, the wiring layer (active layer) 320 is deformed as illustrated in FIG. 3, for example, so as to push up the group of lands 321a over the through hole via 340. A crack may appear near the through hole via 340 as a result of such deformation.

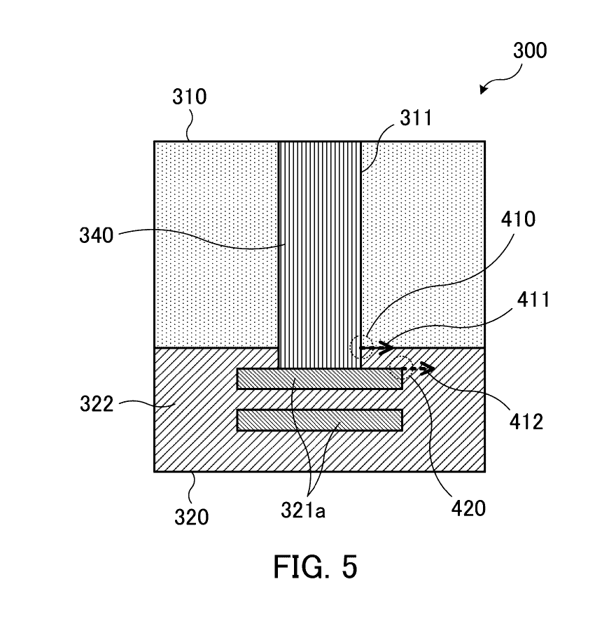

FIG. 5 is a view for describing an example of a crack which appears near the through hole via.

For convenience, FIG. 5 schematically illustrates an example of sections of the through hole via 340 and its peripheral portions at the time of the above chip 300 illustrated in FIGS. 2 and 3 being turned upside down. That is to say, FIG. 5 illustrates the state of the chip 300 in which the wiring layer 320 including the group of lands 321a is disposed under the under surface of the semiconductor substrate 310 having the through hole via 340.

As illustrated in FIG. 5, when a pop-up of the through hole via 340 occurs and as a consequence the wiring layer 320 is deformed, a crack 411 may appear with a part 410 where the semiconductor substrate 310, the through hole via 340, and the insulating portion 322 of the wiring layer 320 are in contact with one another, that is to say, what is called a triple point as a starting point. Furthermore, as illustrated in FIG. 5, a crack 412 may appear with a part 420 of an interface between a first-layer land 321a formed right under the through hole via 340 and directly influenced by the deformation of the through hole via 340 and the insulating portion 322 as a starting point. The appearance of the crack 411 or 412 may lead to, for example, an electrical leakage failure or structural embrittlement. This may lead to deterioration in the performance or quality of the chip 300 and therefore the three-dimensional stacked device using the chip 300.

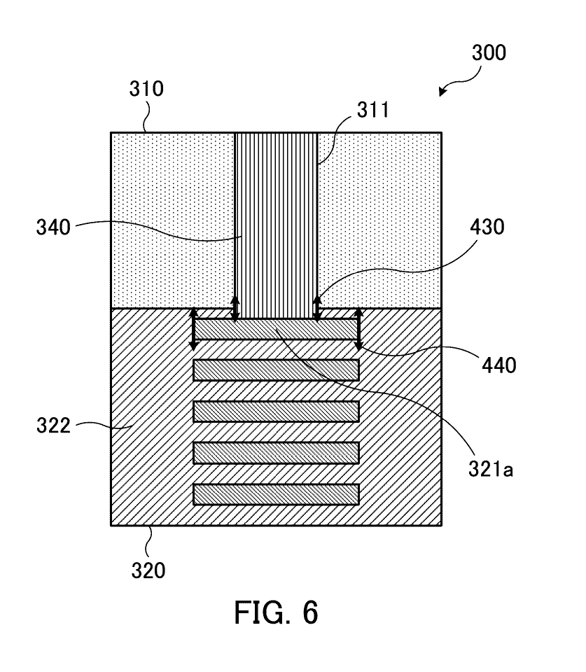

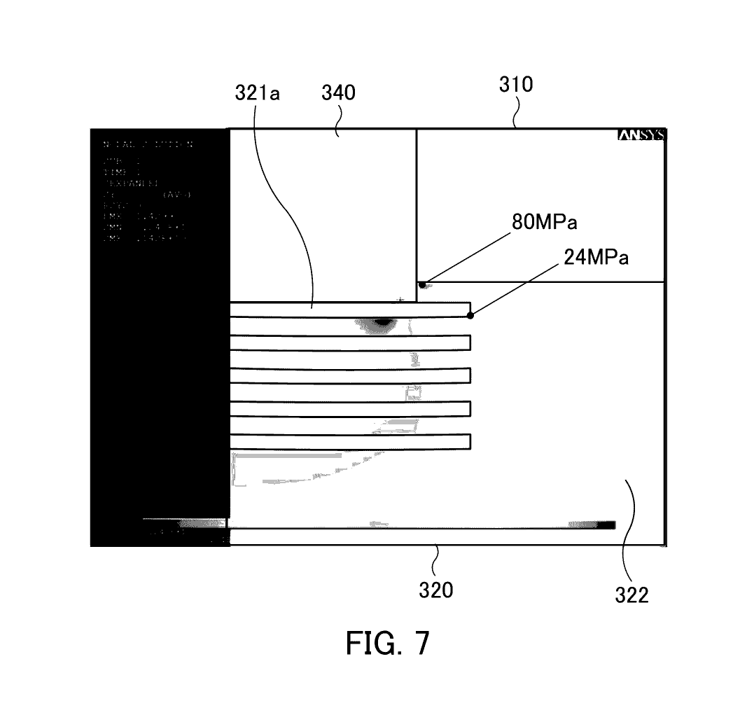

The reason for the appearance of the above crack 411 or 412 will be as follows. FIG. 6 is a view for describing stress (shear stress) created near the through hole via. FIG. 7 indicates an example of the distribution of stress created near the through hole via. FIG. 7 indicates an example of the distribution of stress created near the through hole via in a state in which heat treatment is performed at 400° C.

When the through hole via 340 is heated at a determined temperature, the through hole via 340 pops up from the through hole 311 of the semiconductor substrate 310. As a result, as illustrated in FIG. 6, stress difference made by the thermal expansion of the semiconductor substrate 310, the through hole via 340, and the insulating portion 322 occurs as shear stress 430 at an interface (triple point) between the through hole via 340 and the semiconductor substrate 310 and the insulating portion 322. As indicated in FIG. 7, stress created at the triple point is 80 MPa. The above crack 411 illustrated in FIG. 5 appears due to the shear stress 430 created at the triple point. If copper is used for forming the through hole via 340 and an inorganic insulating material whose Young's modulus is higher than that of copper is used for forming the insulating portion 322, then the insulating portion 322 is hard to deform, compared with the through hole via 340. As a result, the insulating portion 322 cannot withstand the deformation of the through hole via 340 and the crack 411 tends to appear.

In addition, stress created in the through hole via 340 which pops up is transmitted substantially radially to the wiring layer 320 from an under end of the through hole via 340 illustrated in FIG. 6. If copper is used for forming the first-layer land 321a and an inorganic insulating material whose Young's modulus is higher than that of copper is used for forming the insulating portion 322, then stress transmitted radially from the through hole via 340 which pops up is absorbed by slowly deforming the first-layer land 321a. As illustrated in FIG. 6, however, shear stress 440 is created at the interface between an outer edge of the first-layer land 321a and the insulating portion 322 due to the difference in Young's modulus between them. As indicated in FIG. 7, stress created at the outer edge (corner portion) of the first-layer land 321a is 24 MPa. The above crack 412 illustrated in FIG. 5 appears due to the shear stress 440 created at the interface between the outer edge of the first-layer land 321a and the insulating portion 322.

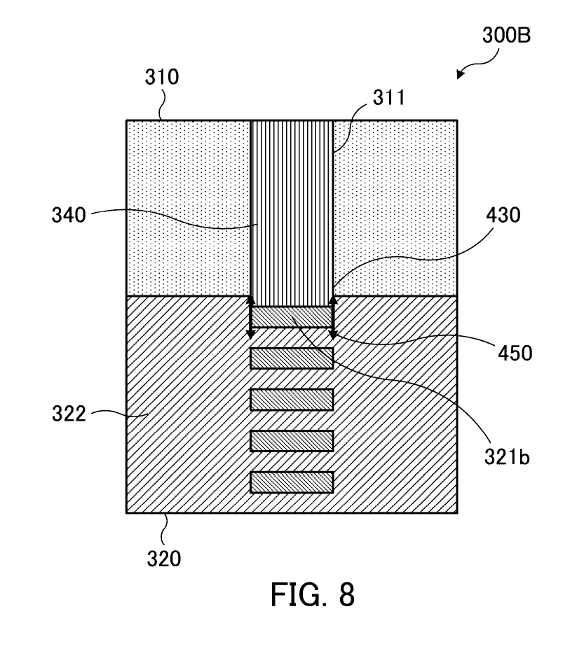

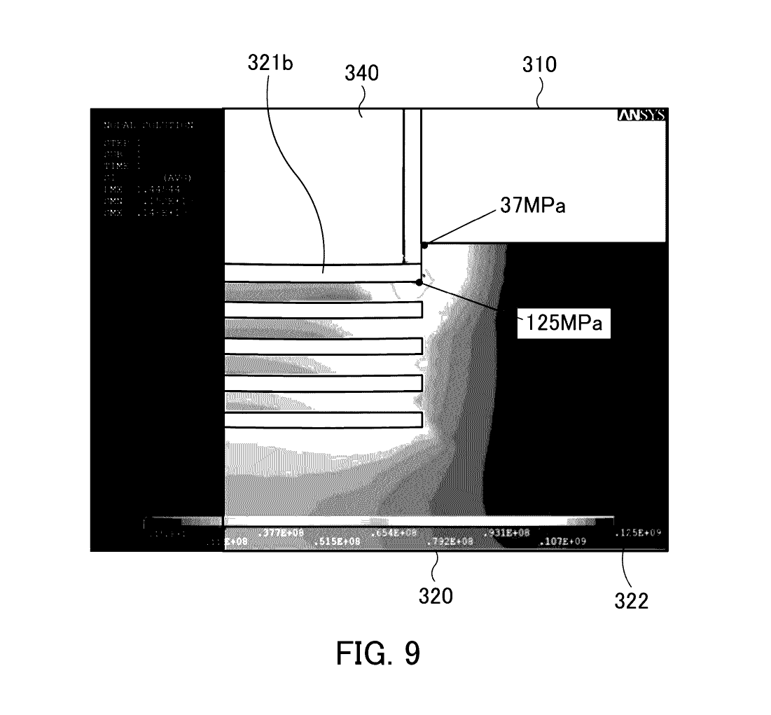

On the other hand, a group of lands formed under the through hole via 340 may have a shape illustrated in FIG. 8. FIG. 8 is a view for describing stress (shear stress) created near a through hole via at the time of forming a group of lands in another shape. FIG. 9 indicates an example of the distribution of stress created near the through hole via at the time of forming the group of lands in another shape. FIG. 9 indicates an example of the distribution of stress created near the through hole via in a state in which heat treatment is performed at 400° C.

FIG. 8 illustrates a chip 300B in which a group of lands 321b equal or practically equal in external size to a through hole via 340 in planar view is formed under the through hole via 340.

As illustrated in FIGS. 8 and 9, if the group of lands 321b which is equal or practically equal in external size to the through hole via 340 is formed in this way under the through hole via 340, shear stress 450 is created at an outer edge of the first-layer land 321b which is in contact with the through hole via 340. As indicated in FIG. 9, stress created at a triple point is 37 MPa. With the chip 300B stress concentration at the triple point is suppressed. On the other hand, however, a great shear stress 450 is created at the corner portion of the first-layer land 321b under the triple point. As indicated in FIG. 9, stress created at the corner portion of the first-layer land 321b is 125 MPa. The first-layer land 321b is in contact with the through hole via 340. When the through hole via 340 pops up, the first-layer land 321b is depressed by the through hole via 340 and is deformed. A surrounding insulating portion 322 cannot withstand the deformation of the first-layer land 321b. As a result, the shear stress 450 is created at an interface between the outer edge of the first-layer land 321b and the insulating portion 322. A crack appears at the interface between the first-layer land 321b and the insulating portion 322 due to the shear stress 450.

As has been described, with the chip 300 (FIGS. 5 through 7) the cracks (411 and 412) tend to appear at the interface (triple point) between the through hole via 340 and the semiconductor substrate 310 and the insulating portion 322 and the interface between the first-layer land 321a and the insulating portion 322, respectively, due to the expansion and deformation of the through hole via 340. In addition, with the chip 300B (FIGS. 8 and 9) a crack also tends to appear at the interface between the first-layer land 321b and the insulating portion 322. The appearance of a crack may lead to a leakage failure or embrittlement of the chip 300 or the chip 300B. This may lead to deterioration in the performance or quality of the chip 300 or the chip 300B and therefore a three-dimensional stacked device using the chip 300 or the chip 300B.

In view of the above problems, structures indicated below as embodiments will be adopted to suppress the appearance of a crack in a wiring layer (multilayer wirings) caused by the expansion and deformation of a through hole via.

First a first embodiment will be described.

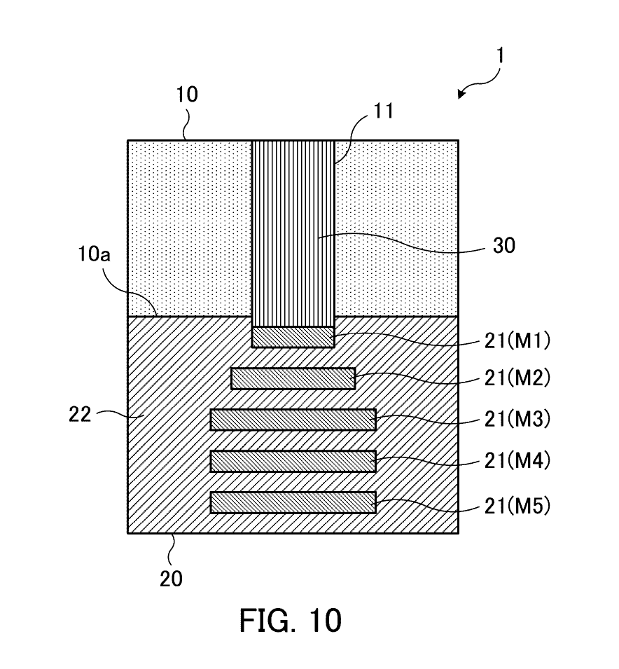

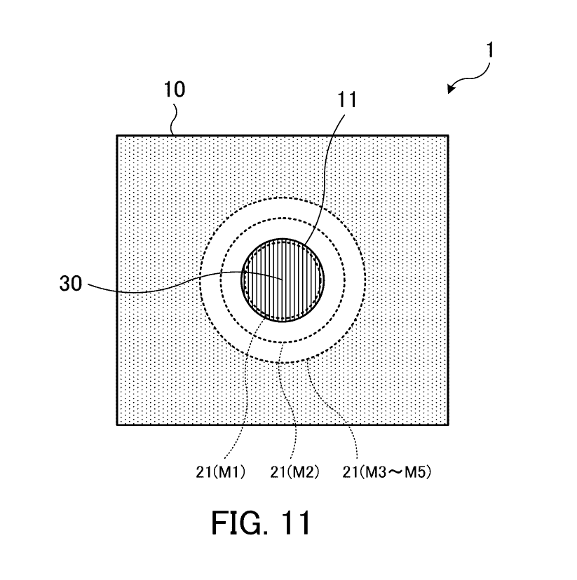

FIGS. 10 and 11 illustrate an example of a chip according to a first embodiment. FIG. 10 is a fragmentary schematic sectional view of an example of a chip according to a first embodiment. FIG. 11 is a fragmentary schematic plan view of the example of the chip according to the first embodiment.

A chip (semiconductor device) 1 illustrated in FIG. 10 includes a semiconductor substrate 10, a wiring layer (multilayer wirings) 20 formed on a front surface 10a side of the semiconductor substrate 10, and a through hole via 30 formed so as to pierce the semiconductor substrate 10.

A semiconductor substrate, such as a Si substrate, is used as the semiconductor substrate 10. Circuit elements, such as transistors, are formed on the front surface (active surface) 10a of the semiconductor substrate 10.

The wiring layer 20 is a wiring layer (active layer or multilayer wirings) formed on the front surface 10a side of the semiconductor substrate 10 and includes a group of lands 21 disposed under the through hole via 30 and an insulating portion 22 which covers the group of lands 21. In addition to the group of lands 21, circuit elements, such as transistors, formed on the semiconductor substrate 10 and a conductor portion (wiring, a via, or the like) electrically connected to a land 21 or the group of lands 21 may be included in the insulating portion 22. FIGS. 10 and 11 illustrate only the group of lands 21 as a conductor portion of the wiring layer 20. A conductor material, such as Cu, is used for forming conductor portions, such as the group of lands 21, of the wiring layer 20. An insulating material, such as SiO, is used for forming the insulating portion 22 of the wiring layer 20.

The through hole via 30 is formed over the group of lands 21 of the wiring layer 20 so as to pierce the semiconductor substrate 10. The through hole via 30 electrically connects the wiring layer 20 formed on the front surface 10a side of the semiconductor substrate 10 and a wiring layer (BEOL) formed on a back surface side of the semiconductor substrate 10. A conductor material, such as Cu, is used for forming the through hole via 30. A side edge portion of the through hole via 30 is, for example, an inorganic or organic insulating film (not illustrated). In that case, a conductor material, such as Cu, is used inside the insulating film. Direct contact of the semiconductor substrate 10 with a conductor material used for forming the through hole via 30 is avoided by the use of the insulating film.

FIG. 10 illustrates five layers of lands M1 through M5 as the group of lands 21 disposed under the through hole via 30.

Of the group of lands 21, the land M1 in the first layer from the through hole via 30 side is disposed so as to be in contact with an end of the through hole via (under surface of the through hole via 30 illustrated in FIG. 10). As illustrated in FIGS. 10 and 11, for example, the first-layer land M1 is equal or practically equal in external size to the through hole via 30 in planar view so that it will not extend outside the through hole via 30. For convenience, FIG. 11 illustrates the first-layer land M1 which is slightly smaller in external size than the through hole via 30. As stated above, however, the first-layer land M1 is equal or practically equal in external size to the through hole via 30.

Of the group of lands 21, the land M2 in the second layer from the through hole via 30 side is disposed under the first-layer land M1 with the insulating portion 22 therebetween. As illustrated in FIGS. 10 and 11, the second-layer land M2 is larger in external size than the first-layer land M1 in planar view.

Of the group of lands 21, the land M3 in the third layer from the through hole via 30 side is disposed under the second-layer land M2 with the insulating portion 22 therebetween. In this example, as illustrated in FIGS. 10 and 11, the third-layer land M3 is larger in external size than the second-layer land M2 in planar view. Similarly, as illustrated in FIGS. 10 and 11, the land M4 in the fourth layer from the through hole via 30 side or the land M5 in the fifth layer from the through hole via 30 side is also larger in external size than the second-layer land M2 in planar view. In this example, the land M4 in the fourth layer from the through hole via 30 side or the land M5 in the fifth layer from the through hole via 30 side is equal or practically equal in external size to the third-layer land M3.

As stated above, with the group of lands 21 of the chip 1, the first layer (land M1) is equal or practically equal in external size to the through hole via 30, and the external sizes of the second layer (land M2) and the third layer (land M3) gradually increase with an increase in the distance from the through hole via 30. By adopting this structure in the chip 1, stress concentration caused by a pop-up of the through hole via 30 is checked.

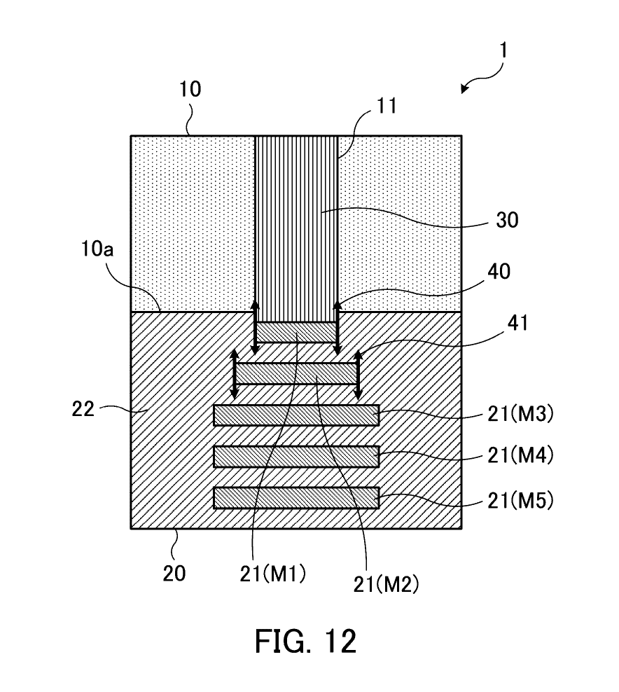

FIG. 12 is a view for describing stress (shear stress) created near the through hole via in the chip according to the first embodiment.

When heating is performed at a determined temperature, the through hole via 30 pops up from a through hole 11 of the semiconductor substrate 10. The through hole via 30, the semiconductor substrate 10, and the insulating portion 22 differ in thermal expansion coefficient. As a result, stress difference made by the thermal expansion of the through hole via 30, the semiconductor substrate 10, and the insulating portion 22 occurs as shear stress 40 at the interface between the through hole via 30 which pops up and the semiconductor substrate 10 and the insulating portion 22. In order to check concentration of the shear stress 40 at the triple point at which the through hole via 30, the semiconductor substrate 10, and the insulating portion 22 are in contact with one another, the external size of the first-layer land M1 of the group of lands 21 is set so that it will not extend in planar view outside the through hole via 30.

Stress in the through hole via 30 which pops up is transmitted radially from the center of its end. If copper is used for forming the land M1 and a material whose Young's modulus is higher than that of copper is used for forming the insulating portion 22, then stress transmitted radially from the through hole via 30 is absorbed by deformation of the land M1. On the other hand, the shear stress 40 is created at an interface between an outer edge of the land M1 and the insulating portion 22 due to the difference in Young's modulus between them. If the external size of the first-layer land M1 is set so that it will not extend in planar view outside the through hole via 30, then stress concentration at the triple point is checked. On the other hand, however, the shear stress 40 may become larger at the interface between the outer edge of the land M1 under the triple point and the insulating portion 22 whose Young's modulus is higher than that of the land M1. Accordingly, the second-layer land M2 is made larger in external size than the first-layer land M1 in planar view to absorb and relax the shear stress 40 created at the interface between the outer edge of the first-layer land M1 and the insulating portion 22 by the second-layer land M2 disposed under the land M1.

If the third-layer land M3, as in this example, is larger in external size than the second-layer land M2, shear stress 41 created at an interface between an outer edge of the second-layer land M2 and the insulating portion 22 is also absorbed and relaxed by the third-layer land M3 disposed under the land M2.

As has been described, with the chip 1 the external size of the first-layer land M1 is set so that it will not extend outside the through hole via 30. The external sizes of the second-layer land M2 and the third-layer land M3 are set so that they will gradually increase with an increase in the distance from the through hole via 30. By doing so, stress concentration at the triple point at which the through hole via 30, the semiconductor substrate 10, and the insulating portion 22 are in contact with one another is checked and stress concentration at the interface between the outer edge of the first-layer land M1 and the insulating portion 22 and stress concentration at the interface between the outer edge of the second-layer land M2 and the insulating portion 22 are checked.

By checking such stress concentration, the appearance of a crack in the wiring layer 20 caused by a pop-up of the through hole via 30 is effectively checked in the chip 1. As a result, a leakage failure or embrittlement caused by a crack is suppressed and a high-performance and high-quality chip 1 is realized. Furthermore, a high-performance and high-quality three-dimensional stacked device using such a chip 1 is realized.

The external size of the lands 21 in the second and later layers, that is to say, the external size of the lands M2 through M5 in this example may be changed by the thickness of the group of lands 21 (thickness of a wiring formed in the wiring layer 20). For example, the second-layer land M2 is made larger in external size than the first-layer land M1 by twice the thickness of the wiring and the third-layer land M3 is made larger in external size than the second-layer land M2 by once the thickness of the wiring.

The external size of the lands 21 in the second and later layers is not limited to this example. The external size of the lands 21 in the second and later layers may be set properly on the basis of the kind of a material for the semiconductor substrate 10, the through hole via 30, the group of lands 21, or the insulating portion 22, the size of the semiconductor substrate 10, the through hole via 30, the group of lands 21, or the insulating portion 22, the magnitude of stress created by a pop-up of the through hole via 30, a transmission range of the stress, or the like.

Stress created in the through hole via 30 which pops up is transmitted substantially radially to the wiring layer 20 from an under end of the through hole via 30 illustrated in FIG. 10 or 12, and gradually decays with transmission. Stress transmitted in this way from the through hole via 30 to the wiring layer 20 tends to sufficiently relax in an area beyond a depth corresponding to half of the external diameter of the through hole via 30, that is to say, beyond a depth corresponding to the radius of the through hole via 30 from the under end of the through hole via 30.

From this point of view, with the chip 1 the external size of the first-layer land 21, of the group of lands 21, is set so that it will not extend outside the through hole via 30. The second-layer land 21 to a land 21 whose depth corresponds to the radius of the through hole via 30 have gradually increasing external sizes. In the example of FIGS. 10 through 12, the first-layer land M1 to the third-layer land M3, of the group of lands 21, have gradually increasing external sizes. On the basis of distance over which or a range in which stress is transmitted in the above way from the through hole via 30, however, the lands 21 in the third and later layers, for example, may be equal or practically equal in external size to the second-layer land 21. Furthermore, the first-layer land M1 to the fourth- or fifth-layer land may have gradually increasing external sizes.

A land 21 in a layer lower than the land 21 whose depth corresponds to the radius of the through hole via 30 may be equal in external size to, larger in external size than, or smaller in external size than a land 21 in a layer one higher than the above layer.

Of the group of lands 21 formed under the through hole via 30, at least one set of vertically adjacent lands 21 may electrically be connected by a via.

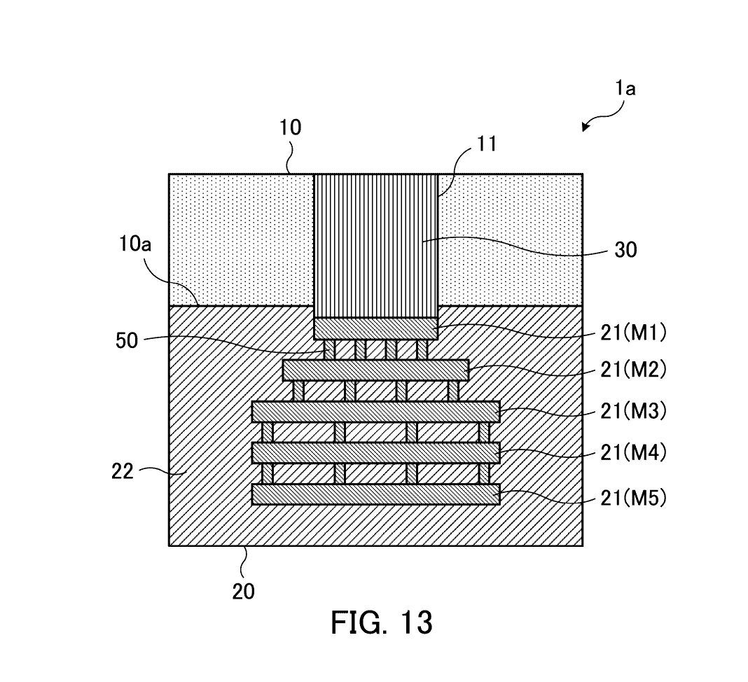

FIG. 13 illustrates another example of the chip according to the first embodiment. FIG. 13 is a fragmentary schematic sectional view of another example of the chip according to the first embodiment.

With a chip (semiconductor device) 1a illustrated in FIG. 13, vertically adjacent lands 21, that is to say, lands M1 and M2, lands M2 and M3, lands M3 and M4, and land M4 and M5, of a group of lands 21 disposed under a through hole via 30, are electrically connected by vias 50. FIG. 13 illustrates only the group of lands 21 and the vias 50 as conductor portions of a wiring layer 20.

In the example of FIG. 13, vertically adjacent lands 21 are electrically connected by a group of vias 50. However, vertically adjacent lands 21 may electrically be connected by at least one via 50.

In the example of FIG. 13, all sets of vertically adjacent lands 21 are electrically connected by groups of vias 50. However, at least one set of vertically adjacent lands 21 may electrically be connected by at least one via 50. A set of vertically adjacent lands 21 not electrically connected by a via 50 may be included in the group of lands 21 disposed under the through hole via 30.

In the above chip 1 or 1a, a land 21 disposed as part of a wiring or a land 21 separated from a wiring in the same layer and disposed so as to have an island shape may be included in the group of lands 21. Furthermore, a dummy land pattern which does not function as part of a circuit may be included in the lands 21 in the second and later layers.

Next, a second embodiment will be described.

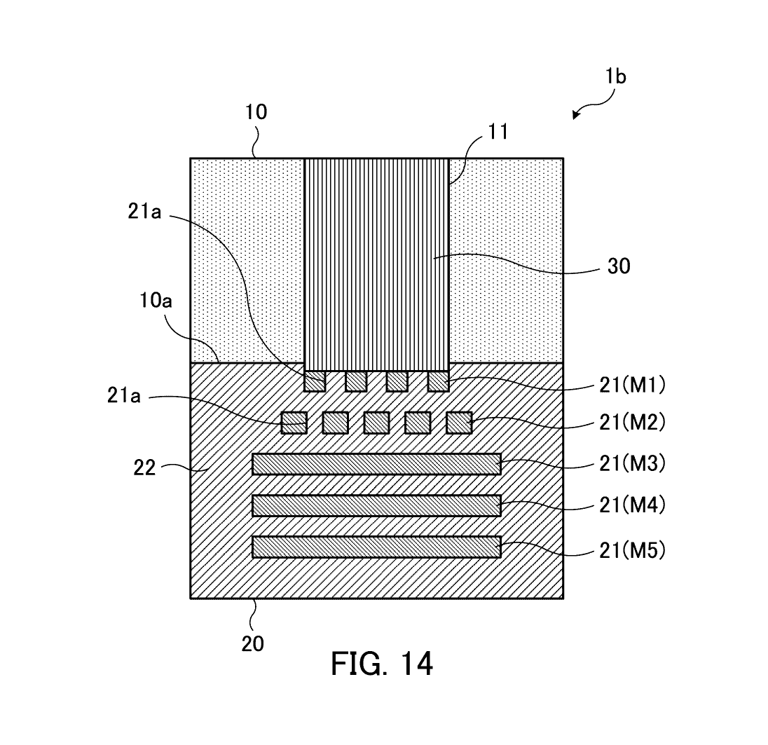

FIG. 14 illustrates an example of a chip according to a second embodiment. FIG. 14 a fragmentary schematic sectional view of an example of a chip according to a second embodiment.

A chip (semiconductor device) 1b illustrated in FIG. 14 differs from the chip 1 or 1a according to the above first embodiment in that opening portions 21a are formed in a first-layer land M1 and a second-layer land M2 of a group of lands 21 disposed under a through hole via 30. FIG. 14 illustrates only the group of lands 21 as conductor portions of a wiring layer 20.

As illustrated in FIG. 14, for example, plural opening portions 21a are formed in each of the first-layer land M1 and the second-layer land M2. As illustrated in FIG. 14, for example, these opening portions 21a are disposed in the following way. A portion other than an opening portion 21a of the second-layer land M2 is disposed under an opening portion 21a formed in the first-layer land M1.

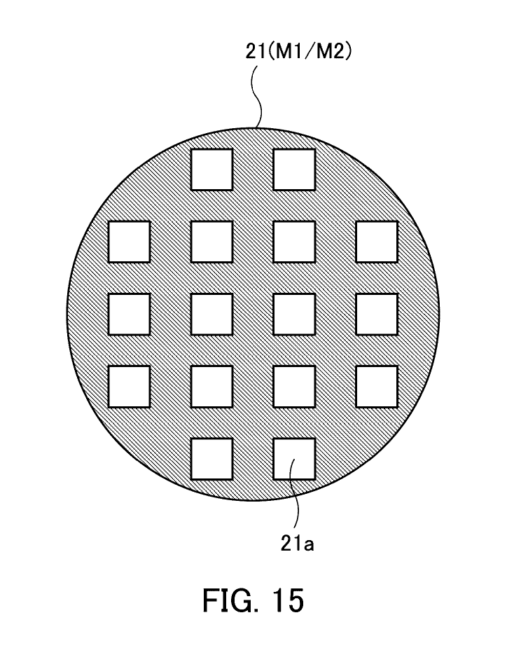

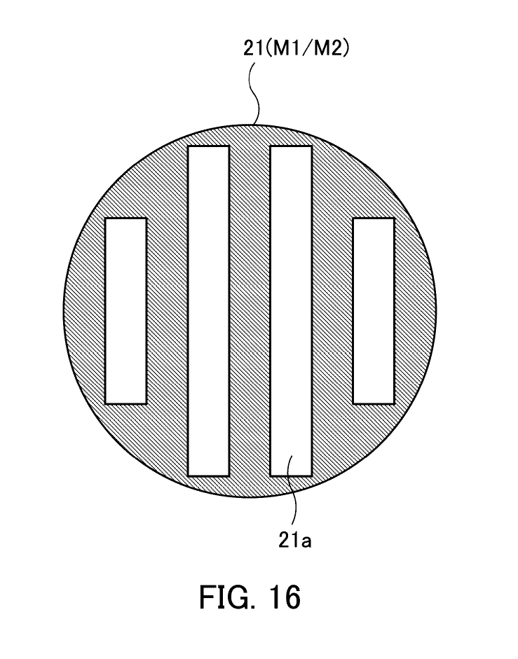

Each of FIGS. 15 and 16 illustrates an example of a land in the second embodiment. Each of FIGS. 15 and 16 is a schematic plan view of an example of a land in the second embodiment.

As illustrated in FIG. 15, for example, the opening portions 21a of the above land 21 (land M1 or M2 in the above example) may be arranged vertically and horizontally in planar view to form the shape of a mesh. Alternatively, the opening portions 21a may be arranged alternately, that is to say, checkerwise in planar view. The plane shape of each opening portion 21a may be rectangular. Alternatively, the plane shape of each opening portion 21a may be circular, elliptic, triangular, or the like.

Furthermore, as illustrated in FIG. 16, for example, opening portions 21a of a land 21 (land M1 or M2 in the above example) may be, in planar view, slits each extending in one direction and disposed in parallel.

As in the example of FIG. 13, lands 21 in each of which the above opening portions 21a are formed may electrically be connected by vias 50.

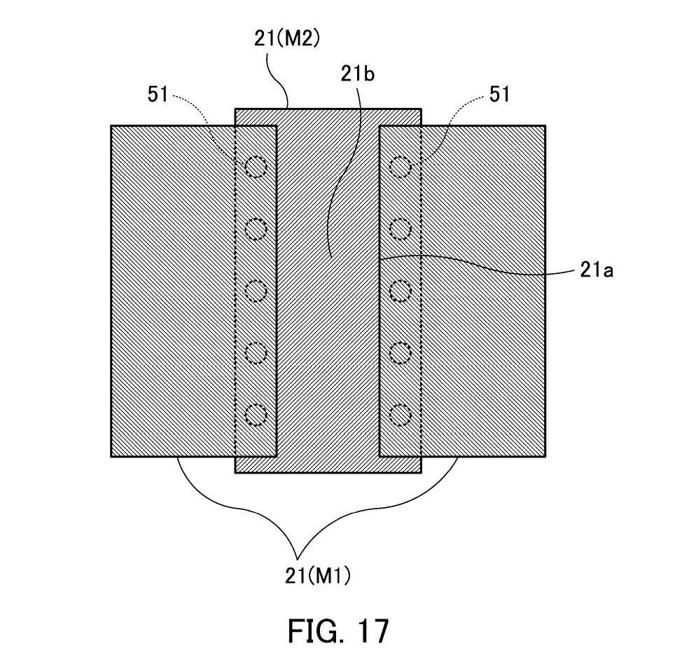

FIG. 17 illustrates an example of connection of lands by vias in the second embodiment. FIG. 17 is a schematic view of a layout of vertically adjacent lands, of the group of lands in the second embodiment, connected by vias.

FIG. 17 partially illustrates the lands M1 and M2, of the group of lands 21 in the chip 1b, in the first and second layers, respectively, from the through hole via 30 side and schematically illustrates a state in which a portion 21b other than an opening portion 21a of the land M2 is disposed under an opening portion 21a of the land M1. The lands M1 and M2 are connected by vias 51 at a portion at which they overlap. A case where the lands M1 and M2 are connected by plural vias 51 at a portion at which they overlap is taken as an example. However, the lands M1 and M2 are connected by at least one via 51.

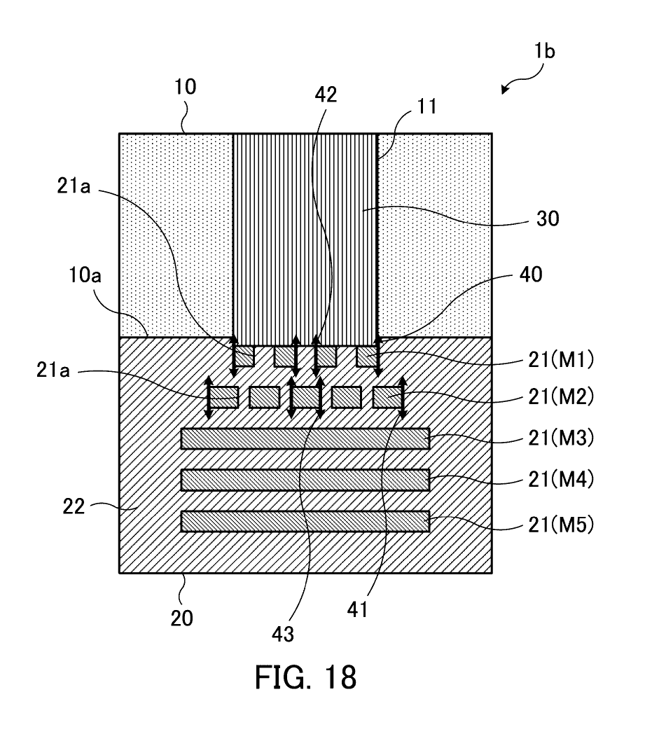

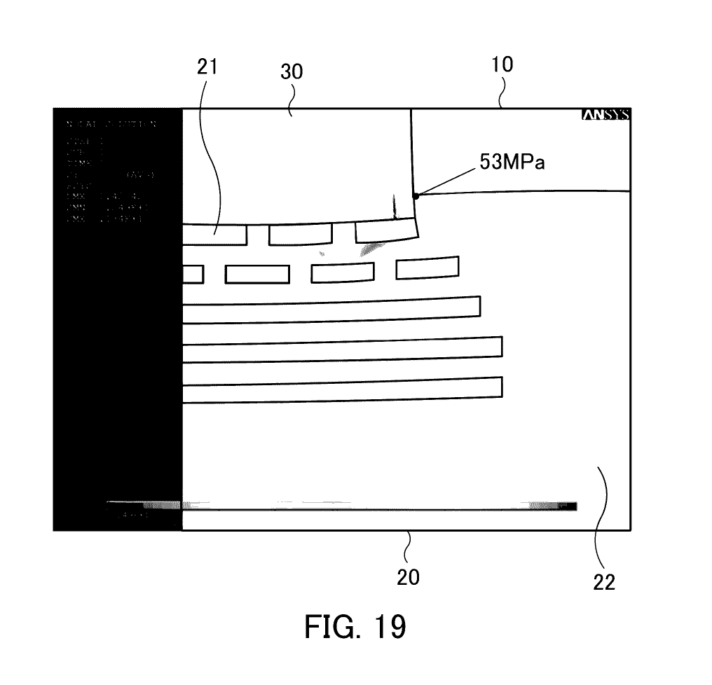

FIG. 18 is a view for describing stress (shear stress) created near the through hole via in the chip according to the second embodiment. FIG. 19 indicates an example of the distribution of stress created near the through hole via in the chip according to the second embodiment.

When heating is performed at a determined temperature, the through hole via 30 in the chip 1b pops up from a through hole 11 of a semiconductor substrate 10. Stress difference made by the thermal expansion of the through hole via 30, the semiconductor substrate 10, and an insulating portion 22 occurs as shear stress 40 at an interface between an outer edge of the through hole via 30 which pops up and the semiconductor substrate 10 and the insulating portion 22. This is the same with the above chip 1. With the chip 1b the external size of the first-layer land M1 is set so that it will not extend in planar view outside the through hole via 30. By doing so, concentration of the shear stress 40 (FIG. 19) at a triple point at which the through hole via 30, the semiconductor substrate 10, and the insulating portion 22 are in contact with one another is checked. As indicated in FIG. 19, stress created at the triple point is 53 MPa.

Stress concentration at the triple point is checked in this way. On the other hand, the second-layer land M2 is made larger in external size than the first-layer land M1 in planar view to absorb and relax the shear stress 40 created at an interface between an outer edge of the land M1 and the insulating portion 22 by the second-layer land M2. Similarly, shear stress 41 created at an interface between an outer edge of the second-layer land M2 and the insulating portion 22 is absorbed and relaxed by a third-layer land M3 which is made larger in external size than the land M2.

With the chip 1b shear stress 42 may also be created at an interface between an inner wall of an opening portion 21a formed in the first-layer land M1 and the insulating portion 22 in the opening portion 21a. Forming the opening portions 21a in the first-layer land M1 checks concentration of stress created in the through hole via 30 which pops up in the land M1 and reduces a deformation amount of the land M1. The shear stress 42 created as a result of forming the opening portions 21a in the land M1 is absorbed and relaxed by the second-layer land M2.

Similarly, forming the opening portions 21a in the second-layer land M2 checks concentration of stress transmitted from the first-layer land M1 side and reduces a deformation amount of the land M2. Shear stress 43 created at an interface between an inner wall of an opening portion 21a formed in the second-layer land M2 and the insulating portion 22 in the opening portion 21a is absorbed and relaxed by the third-layer land M3.

As has been described, with the chip 1b the external size of the first-layer land M1 is set so that it will not extend outside the through hole via 30. The external sizes of the second-layer land M2 and the third-layer land M3 are set so that they will gradually increase with an increase in the distance from the through hole via 30. Furthermore, the opening portions 21a are formed in the first-layer land M1 and the second-layer land M2. By doing so, stress concentration at the triple point, interfaces between the land M1 having the opening portions 21a and the insulating portion 22, or interfaces between the land M2 having the opening portions 21a and the insulating portion 22 is checked. As a result, the appearance of a crack is suppressed and a leakage failure or embrittlement caused by a crack is suppressed. Accordingly, a high-performance and high-quality chip 1b is realized. In addition, a high-performance and high-quality three-dimensional stacked device using such a chip 1b is realized.

As illustrated in FIG. 14, a layout in which a portion other than an opening portion 21a of the second-layer land M2 is disposed under an opening portion 21a formed in the first-layer land M1 is taken as an example. However, the layout of opening portions 21a is not limited to this example.

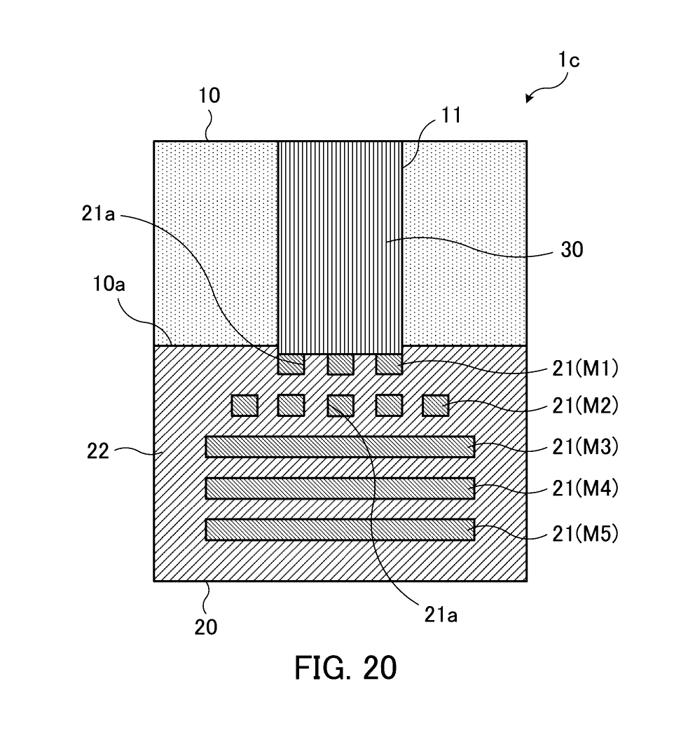

FIG. 20 illustrates another example of the chip according to the second embodiment. FIG. 20 is a fragmentary schematic sectional view of another example of the chip according to the second embodiment.

A chip (semiconductor device) 1c illustrated in FIG. 20 has a structure in which opening portions 21a are disposed at facing positions in lands M1 and M2 in first and second layers, respectively, from a through hole via 30 side. FIG. 20 illustrates only a group of lands 21 as conductor portions of a wiring layer 20.

Even if this disposition is adopted, stress concentration at a triple point, interfaces between the land M1 having the opening portions 21a and an insulating portion 22, or interfaces between the land M2 having the opening portions 21a and the insulating portion 22 is checked. This is the same with the above chip 1b. As a result, the appearance of a crack is suppressed and a leakage failure or embrittlement caused by a crack is suppressed. Accordingly, a high-performance and high-quality chip 1c is realized. In addition, a high-performance and high-quality three-dimensional stacked device using such a chip 1c is realized.

In the chip 1c, all of the opening portions 21a in the first-layer land M1 and all of the opening portions 21a in the second-layer land M2 may be at facing positions or part of the opening portions 21a in the first-layer land M1 and part of the opening portions 21a in the second-layer land M2 may be at facing positions.

Furthermore, the chip 1b or 1c in which the opening portions 21a are formed in the first-layer land M1 and the second-layer land M2 is taken as an example. However, opening portions 21a may be formed in the same way in a third-layer land M3, a fourth-layer land M4, and a fifth-layer land M5.

If at least one opening portion 21a is formed in each land 21 (in the lands M1 and M2, for example), the above effect is obtained.

Next, a third embodiment will be described.

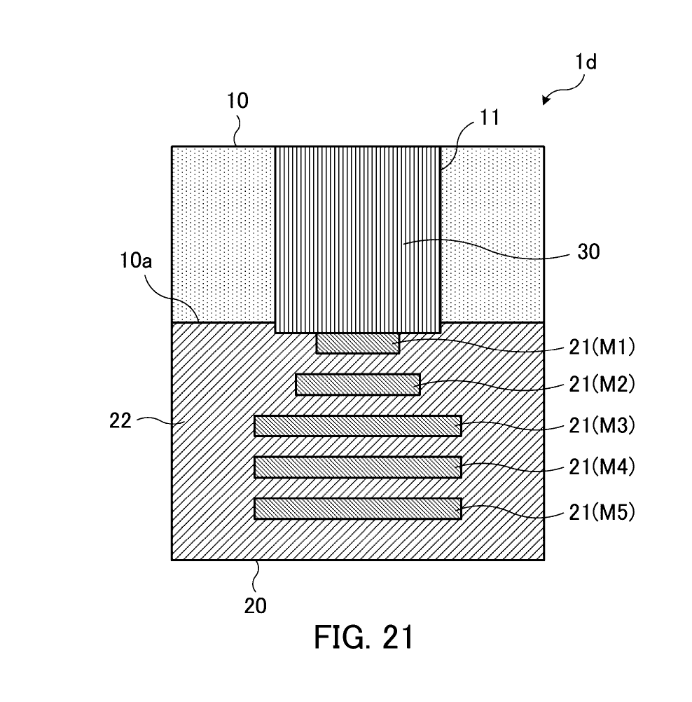

FIG. 21 illustrates an example of a chip according to a third embodiment. FIG. 21 is a fragmentary schematic sectional view of an example of a chip according to a third embodiment.

With a chip (semiconductor device) 1d illustrated in FIG. 21, a land M1, of a group of lands 21, in a first layer from a through hole via 30 side is smaller in external size than a through hole via 30 in planar view. The chip 1d according to the third embodiment differs from, for example, the above chip 1 according to the first embodiment in this respect. FIG. 21 illustrates only the group of lands 21 as conductor portions of a wiring layer 20.

In the chip 1d, a land M2 in a second layer from the through hole via 30 side is larger in external size than the first-layer land M1 in planar view. In this example, the second-layer land M2 is smaller in external size than the through hole via 30 in planar view. Lands M3 to M5 in third and later layers from the through hole via 30 side are larger in external size than the second-layer land M2 in planar view.

In the chip 1d, the first-layer land M1 is smaller in external size than the through hole via 30 in planar view. This checks stress concentration at a triple point at which the through hole via 30, a semiconductor substrate 10, and an insulating portion 22 are in contact with one another. Shear stress created at an interface between an outer edge of the first-layer land M1 and the insulating portion 22 is absorbed and relaxed by the second-layer land M2. Shear stress at the triple point decays at the time of being transmitted in the insulating portion 22, and is absorbed and relaxed by the second-layer land M2 and the third-layer land M3. Shear stress created at an interface between an outer edge of the second-layer land M2 and the insulating portion 22 is absorbed and relaxed by the third-layer land M3.

With the chip 1d stress concentration at the time of a pop-up of the through hole via 30 is checked in this way. As a result, the appearance of a crack is suppressed and a leakage failure or embrittlement caused by a crack is suppressed. Accordingly, a high-performance and high-quality chip 1d is realized. In addition, a high-performance and high-quality three-dimensional stacked device using such a chip 1d is realized.

In this example, the second-layer land M2 is smaller in external size than the through hole via 30 in planar view. However, the external size of the land M2 is not limited to this example. For example, the land M2 may be equal or practically equal in external size to the through hole via 30 in planar view or be larger in external size than the through hole via 30 in planar view. Even in these cases, shear stress created at the triple point or at the interface between the outer edge of the land M1 and the insulating portion 22 is absorbed and relaxed. This is the same with the above case. The external size of the land M2, M3, M4, or M5 may be set properly on the basis of the kind of a material for the semiconductor substrate 10, the through hole via 30, the group of lands 21, or the insulating portion 22, the size of the semiconductor substrate 10, the through hole via 30, the group of lands 21, or the insulating portion 22, the magnitude of stress created by a pop-up of the through hole via 30, a transmission range of the stress, or the like.

The group of lands 21 in the chip 1d according to the third embodiment, as in the above example of FIG. 13, may also be connected electrically by vias 50.

Next, a fourth embodiment will be described.

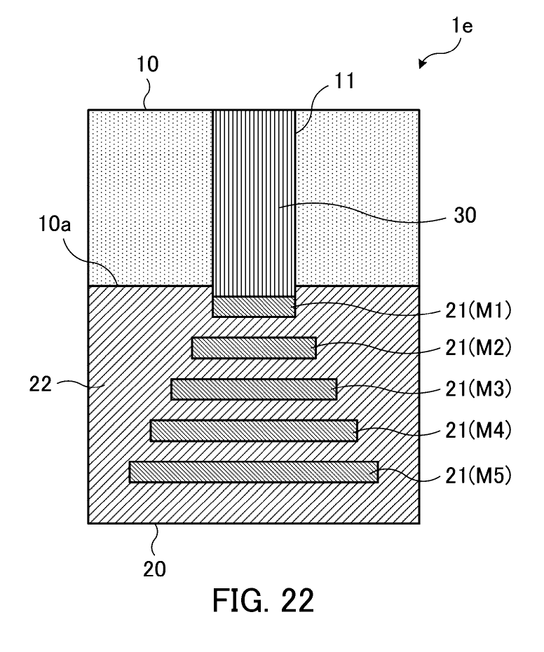

FIG. 22 illustrates an example of a chip according to a fourth embodiment. FIG. 22 is a fragmentary schematic sectional view of an example of a chip according to a fourth embodiment.

With a chip (semiconductor device) 1e illustrated in FIG. 22, a land M4, of a group of lands 21, in a fourth layer from a through hole via 30 side is larger in external size than a land M3 in a third layer from the through hole via 30 side in planar view. A land M5 in a fifth layer from the through hole via 30 side is larger in external size than the fourth-layer land M4 in planar view. That is to say, the external sizes of the lands 21 in the chip 1e gradually increase with an increase in the distance from the through hole via 30. The chip 1e according to the fourth embodiment differs from the above chip 1 or 1a according to the first embodiment in this respect. FIG. 22 illustrates only the group of lands 21 as conductor portions of a wiring layer 20.

With the above chip 1e shear stress created at an interface between an outer edge of the third-layer land M3 and an insulating portion 22 is absorbed and relaxed by the fourth-layer land M4. Furthermore, shear stress created at an interface between an outer edge of the fourth-layer land M4 and the insulating portion 22 is absorbed and relaxed by the fifth-layer land M5.

For example, if the through hole via 30 has a large external diameter or a displacement amount of the through hole via 30 is large, stress created as a result of a pop-up is large. In such a case, the group of lands 21 of FIG. 22 whose external sizes gradually increase with an increase in the distance from the through hole via 30 is preferable.

In addition, it is assumed that there is a land in a layer lower than a land 21 at a depth (corresponding to the radius of the through hole via 30, for example) at which transmitted stress is sufficiently relaxed. Even in such a case, stress concentration is effectively checked by making the land 21 in that layer larger in external size than a land 21 in a layer one higher than that layer.

According to the fourth embodiment, the appearance of a crack is suppressed and a leakage failure or embrittlement caused by a crack is suppressed. Accordingly, a high-performance and high-quality chip 1e is realized. In addition, a high-performance and high-quality three-dimensional stacked device using such a chip 1e is realized.

The group of lands 21 in the chip 1e according to the fourth embodiment, as in the above example of FIG. 13, may also be connected electrically by vias 50.

Next, a fifth embodiment will be described.

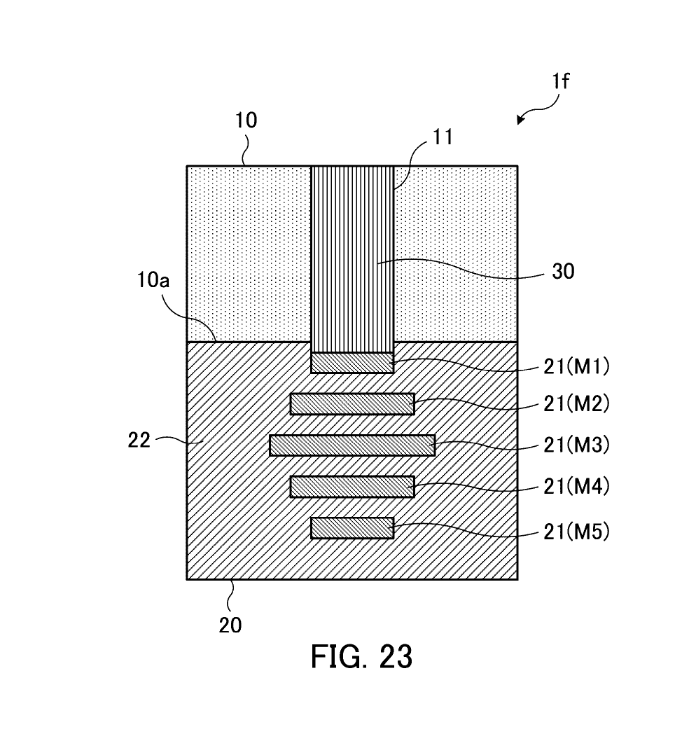

FIG. 23 illustrates an example of a chip according to a fifth embodiment. FIG. 23 is a fragmentary schematic sectional view of an example of a chip according to a fifth embodiment.

With a chip (semiconductor device) 1f illustrated in FIG. 23, a land M4, of a group of lands 21, in a fourth layer from a through hole via 30 side is smaller in external size than a land M3 in a third layer from the through hole via 30 side in planar view. A land M5 in a fifth layer from the through hole via 30 side is smaller in external size than the fourth-layer land M4 in planar view. That is to say, with the group of lands 21 in the chip 1f the external sizes of lands M1 to M3 in first to third layers, respectively, gradually increase with an increase in the distance from the through hole via 30. The external sizes of the lands M4 and M5 in the fourth and fifth layers, respectively, gradually decrease with an increase in the distance from the through hole via 30. The chip 1f according to the fifth embodiment differs from the above chip 1 or 1a according to the first embodiment in this respect. FIG. 23 illustrates only the group of lands 21 as conductor portions of a wiring layer 20.

For example, if stress transmitted to the wiring layer 20 from the through hole via 30 which pops up is sufficiently relaxed when or before it reaches the depth of the third-layer land M3, then the lands M4 and M5 in the fourth and fifth layers, respectively, may have gradually decreasing sizes, as illustrated in FIG. 23, with an increase in the distance from the through hole via 30.

According to the fifth embodiment, the appearance of a crack is also suppressed and a leakage failure or embrittlement caused by a crack is also suppressed. Accordingly, a high-performance and high-quality chip 1f is realized. In addition, a high-performance and high-quality three-dimensional stacked device using such a chip 1f is realized.

Furthermore, according to the fifth embodiment, the area of lands 21 in layers at and beyond a depth at which stress transmitted from the through hole via 30 is sufficiently relaxed is reduced. By doing so, the cost of a material for the conductor portions formed in the wiring layer 20 is reduced and the flexibility of the layout of the conductor portions except the lands 21 is improved.

The group of lands 21 in the chip 1f according to the fifth embodiment, as in the above example of FIG. 13, may also be connected electrically by vias 50.

Next, a sixth embodiment will be described.

The chip 1 described in the above first embodiment is taken as an example. An example of a method for fabricating the chip 1 and an example of a method for fabricating a three-dimensional stacked device using the fabricated chip 1 will now be described as a sixth embodiment.

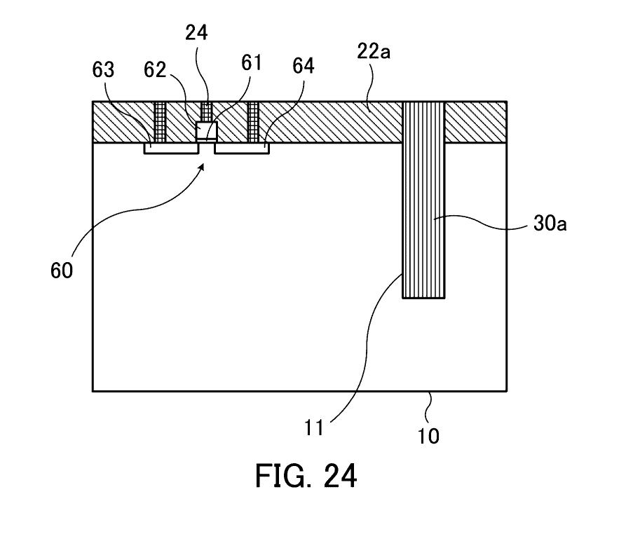

First an example of a method for fabricating the chip 1 will be described with reference to FIGS. 24 to 27.

FIGS. 24 to 27 illustrate an example of a chip fabrication method according to a sixth embodiment. Each of FIGS. 24 to 27 is a fragmentary schematic sectional view of a fabrication process according to a sixth embodiment.

As illustrated in FIG. 24, first a via 30a (above through hole via 30) is formed in the semiconductor substrate 10 which is a Si substrate or the like and on which a circuit element is formed.

A metal oxide semiconductor field effect transistor (MOSFET) 60 is taken as an example of the circuit element formed on the semiconductor substrate 10. The MOSFET 60 has a gate electrode 62 formed over the semiconductor substrate 10 with a gate insulating film 61 therebetween and impurity regions 63 and 64 which are formed in the semiconductor substrate 10 on both sides of the gate electrode 62 and which function as a source region and a drain region. In addition to the MOSFET 60, another circuit element, such as a resistor or a capacitor, may be formed on the semiconductor substrate 10.

An insulating layer 22a (part of the above insulating portion 22) is formed over the semiconductor substrate 10 on which the MOSFET 60 is formed so as to cover the MOSFET 60. The insulating layer 22a is formed by the use of an insulating material such as SiO or SiN. Plugs 24 electrically connected to the gate electrode 62 and the impurity regions 63 and 64 of the MOSFET 60 are formed in the insulating layer 22a. The plugs 24 are formed by the use of a conductor material such as W.

The via 30a which pierces the insulating layer 22a formed over the semiconductor substrate 10 so as to reach the inside of the semiconductor substrate 10 is formed.

At this time a resist pattern having an opening portion in a region where the via 30a is to be formed is formed first over the insulating layer 22a. The thickness of the resist pattern is, for example, 10 μm and the diameter of the opening portion is, for example, 10 μm.

Next, the insulating layer 22a and the semiconductor substrate 10 are etched with the resist pattern as a mask. If the semiconductor substrate 10 is a Si substrate, then mixed gas of, for example, SF₆ and octafluorocyclobutane (C₄F₈) is used and dry etching is performed under the following conditions. Pressure is 0.1 Torr (≈133.322 Pa), input power is 500 W, and an etching rate is 20 μm/min. Etching time is controlled and the through hole 11 having a depth of, for example, 75 μm from the surface 10a of the semiconductor substrate 10 is made. The diameter of the through hole 11 is 10 μm corresponding to the diameter of the opening portion of the above resist pattern.

After the through hole 11 is made, an insulating film (not illustrated), such as an oxide film, is formed on an inner wall of the through hole 11 and a barrier film (not illustrated) is formed by the use of metal, such as tantalum (Ta) or titanium (Ti), or its nitride. Furthermore, the through hole 11 is filled with a determined conductor material to form the via 30a. For example, the through hole 11 is filled in by copper electroplating and the via 30a containing copper is formed.

After the via 30a is formed, heat treatment is performed at a determined temperature for, for example, stabilization (crystallization, crystal grain growth, unnecessary component removal, or the like) of the conductor material.

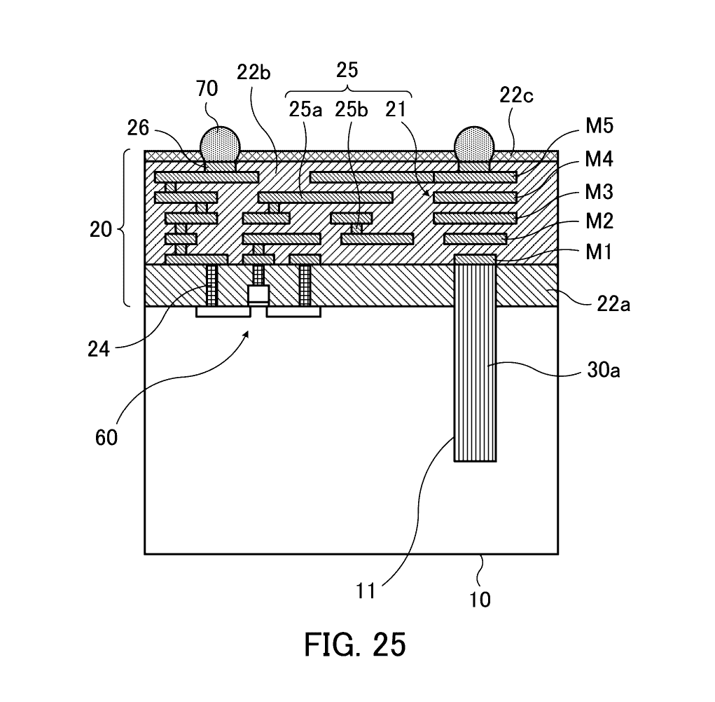

Next, as illustrated in FIG. 25, the rest of the wiring layer 20 which are to be formed over the semiconductor substrate 10 are formed.

For example, the damascene method or the dual damascene method is used for forming an insulating layer 22b (part of the above insulating portion 22) and conductor layers 25 (wirings 25a, vias 25b, and lands 21) included in the rest of the wiring layer 20. In this case, the insulating layer 22b is formed by the use of an insulating material such as SiO, SiN, silicon carbide (SiC), carbon-containing silicon oxide (SiOC), or nitrogen-containing silicon oxide (SiON). The conductor layers 25 are formed by the use of a conductor material such as Cu. Furthermore, the conductor layers 25 illustrated in FIG. 25 may be formed by the use of aluminum (Al).

Of the group of lands 21 in the conductor layers 25, for example, a land M1 in a first layer from a via 30a side is equal in external size to the via 30a, that is to say, the external size of the first-layer land M1 is 10 μm. A second-layer land M2 is larger in external size than the first-layer land M1, that is to say, the external size of the second-layer land M2 is 12 μm. Furthermore, the external size of a third-layer land M3 is 14 μm. A fourth-layer land M4 and a fifth-layer land M5 are equal in external size and their external size is 14 μm. The external sizes of the first-layer land M1, the second-layer land M2, and the third-layer land M3 of the group of lands 21 gradually increase with an increase in the distance from the via 30a.

In addition, together with the group of lands 21, vias 50 (not illustrated) which electrically connect vertically adjacent lands 21 may be formed, as in the above chip 1a illustrated in FIG. 13, at the time of forming the conductor layers 25.

In this example, five layers of the wirings 25a and the lands 21 are illustrated as the conductor layers 25. However, the number of layers of the conductor layers 25 is not limited to this example.

A pad 26 is formed over the uppermost conductor layer 25, and a protection film 22c (part of the above insulating portion 22) is formed so that at least part of the pad 26 will be exposed.

As a result, the wiring layer 20 including the insulating portion 22 and the plugs 24, the wirings 25a, the vias 25b, and the lands 21 in the insulating portion 22, which are conductor portions, is formed over the semiconductor substrate 10 on which the MOSFET 60 is formed. A bump 70 made of solder or the like is formed over the pad 26 which is exposed from the protection film 22c.

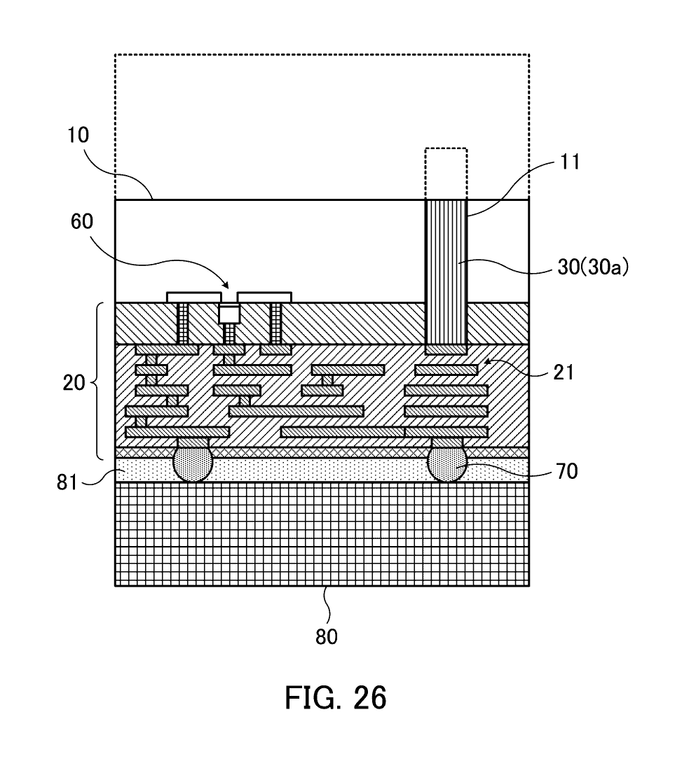

As illustrated in FIG. 26, a board in which the wiring layer 20 is formed over the semiconductor substrate 10 is then bonded with an adhesive 81 to a support 80 with a wiring layer 20 side opposite the support 80. Furthermore, the semiconductor substrate 10 is ground from a back surface side (from a side opposite the wiring layer side) by the back grinding method to a thickness of, for example, 80 μm (indicated by a dotted line in FIG. 26). By grinding the semiconductor substrate 10 in this way, the via 30a gets exposed and the through hole via 30 which pierces the semiconductor substrate 10 is formed.

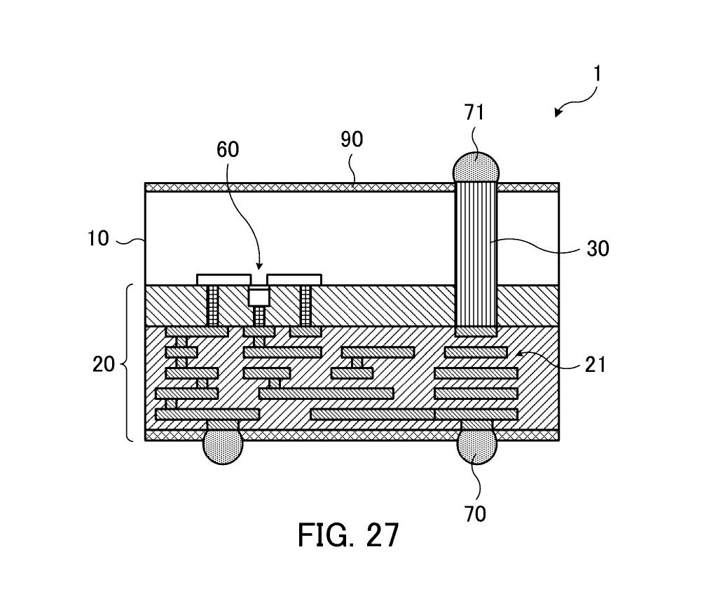

Next, as illustrated in FIG. 27, the semiconductor substrate 10 is etched so that an end portion of the through hole via 30 will get exposed. For example, by wet-etching the semiconductor substrate 10, an end portion of the through hole via 30 gets exposed from the semiconductor substrate 10. After that, a protection film 90 is formed. For example, a bump 71 made of solder or the like is formed over an end of the through hole via 30 which gets exposed.

Before the protection film 90 is formed, a wiring layer (rewiring layer) may be formed over a surface of the semiconductor substrate 10 on which the end portion of the through hole via 30 is exposed, and the protection film 90 may be formed over the surface of the wiring layer. Furthermore, the bump 71 may be formed over a conductor portion (pad) of the rewiring layer which is exposed from the protection film 90.

The chip 1 described in the above first embodiment and including the through hole via 30 and the group of lands 21 of determined external size is fabricated through the above processes.

In this example, the method for fabricating the chip 1 (and the chip 1a) described in the above first embodiment is described. However, the chips 1b and 1c, 1d, 1e, and 1f described in the above second through fifth embodiments, respectively, are also fabricated in accordance with the example illustrated in FIGS. 24 through 27.

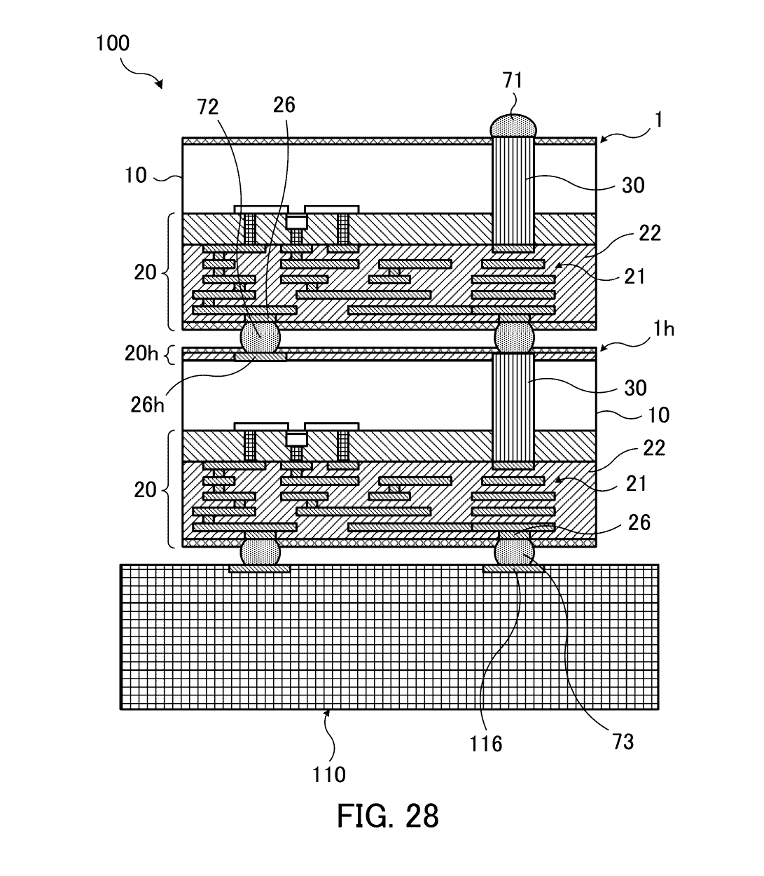

Next, an example of a method for fabricating a three-dimensional stacked device will be described with reference to FIG. 28.

FIG. 28 illustrates an example of a three-dimensional stacked device fabrication method according to the sixth embodiment. FIG. 28 is a fragmentary schematic sectional view of a three-dimensional stacked device fabrication process according to the sixth embodiment.

For example, chips 1 or the like fabricated through the above processes illustrated in FIGS. 24 through 27 are stacked and a three-dimensional stacked device (electronic device) 100 illustrated in FIG. 28 is fabricated. In this case, the three-dimensional stacked device 100 in which two chips (semiconductor devices (boards)) 1 and 1h are stacked over a circuit board 110 is taken as an example. The two chips 1 and 1h are equal in the structure of a group of lands 21. For example, the chip 1h is equal in structure to the chip 1. However, the chip 1h differs from the chip 1 only in that it has a rewiring layer 20h including a pad 26h on a back surface side (on a side opposite a wiring layer 20 side) of a semiconductor substrate 10.

A conductor portion (pad 26) of a wiring layer 20 of the chip 1 and a conductor portion (pad 26h and a through hole via 30) of the rewiring layer 20h of the chip 1h over which the chip 1 is disposed are joined by a bump 72. As a result, the chips 1 and 1h are electrically connected. A conductor portion (pad 26) of a wiring layer 20 of the chip 1h (chip 1h alone or the chip 1h over which the chip 1 is disposed) and a conductor portion (pad 116) of the circuit board 110 over which the chip 1h is disposed are joined by a bump 73. As a result, the chip 1h and the circuit board 110 are electrically connected. Joining the chip 1 and the chip 1h by the bump 72 and joining the chip 1h and the circuit board 110 by the bump 73 are realized by using solder for forming the bump 72 and the bump 73 and by performing reflow.

For example, joining was performed at a reflow temperature of 350° C. and the three-dimensional stacked device 100 was obtained. In this three-dimensional stacked device 100, the through hole via 30 pops up at the reflow temperature. However, the appearance of a crack was not observed at an interface between a semiconductor substrate 10 and an insulating portion 22 or interfaces between a group of lands 21 and an insulating portion 22.

In this example, a case where the chip 1h and the chip 1 are stacked over the circuit board 110 is taken. However, the kind or number of chips stacked over the circuit board 110 is not limited to this example. Furthermore, chips are not necessarily stacked over the circuit board 110. That is to say, chips may be stacked over a pseudo-SoC or another chip. In addition, a relay substrate, such as a Si interposer or a printed circuit board, may be disposed between the circuit board 110 or the like in the undermost layer and a chip in the uppermost layer of chips stacked over the circuit board 110 or the like.

As has been described in the foregoing, the external size of the land M1 in the first layer from the through hole via 30 side, of the group of lands 21 disposed under (or over) the through hole via 30 which pierces the semiconductor substrate 10, is set so that it will not extend outside the through hole via 30 in planar view. The land M2 in the second layer from the through hole via 30 side is made larger in external size than the land M1 in planar view. The group of lands 21 includes at least the lands M1 and M2 whose external size is set in this way, and has two or more layers. If this condition is met, then there is no limit to the number of layers the group of lands 21 has. The external size of the lands 21 in the third and later layers is set properly on the basis of the kind of a material for the semiconductor substrate 10, the through hole via 30, the group of lands 21, or the insulating portion 22, the size of the semiconductor substrate 10, the through hole via 30, the group of lands 21, or the insulating portion 22, the magnitude of stress created by a pop-up of the through hole via 30, a transmission range of the stress, or the like. By disposing the above group of lands 21 under (or over) the through hole via 30, local concentration in the wiring layer of stress transmitted from the through hole via 30 which pops up to the wiring layer disposed thereunder (or thereover) is checked and the appearance of a crack caused by stress is checked.

Each land 21 in the group of lands 21 may be circular in plane shape. However, each land 21 in the group of lands 21 may have another shape. For example, each land 21 in the group of lands 21 may be rectangular in plane shape. Even if each land 21 in the group of lands 21 is, for example, rectangular in plane shape, the effect of checking stress concentration, which is the same as that described above, is obtained as long as at least the condition that the external size of the land M1 in the first layer from the through hole via 30 side is set so that it will not extend outside the through hole via 30 in planar view and that the land M2 in the second layer is larger in external size than the land M1 in planar view is met. Furthermore, as in the above example of FIG. 14 or 16, for example, at least one opening portion 21a may be formed in a land 21 which is, for example, rectangular in plane shape. In addition, lands 21 which are circular in plane shape and lands 21 which are, for example, rectangular in plane shape may mingle in the group of lands 21.

According to the disclosed techniques, the appearance of a crack in multilayer wirings caused by a pop-up of a through hole via which pierces a semiconductor substrate is suppressed and a high-performance and high-quality semiconductor device is realized. In addition, a high-performance and high-quality electronic device including such a semiconductor device is realized.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that various changes, substitutions, and alterations could be made hereto without departing from the spirit and scope of the invention.

What is claimed is:

1. A semiconductor device comprising:
a semiconductor substrate;
a through hole via which pierces the semiconductor substrate; and
multilayer wirings disposed under the semiconductor substrate and including plural layers of a group of lands disposed under the through hole via,
the group of lands including:
a first land in a first layer from a through hole via side which is disposed on an under surface of the through hole via and which is equal in external size to or smaller in external size than the through hole via in planar view; and
a second land in a second layer from the through hole via side which is disposed under the first land and which is larger in external size than the first land in the planar view.

2. The semiconductor device according to claim 1, wherein at least one of the first land and the second land has at least one opening portion.

3. The semiconductor device according to claim 1, wherein:
n layers of the group of lands is disposed under the through hole via, where n≧3; and
an ith land in an ith layer, of third to mth layers, from the through hole via side is larger in external size than an (i−1)th land in an (i−1)th layer from the through hole via side in the planar view, where 3≦m<n and 3≦i≦m.

4. The semiconductor device according to claim 1, wherein:
n layers of the group of lands is disposed under the through hole via, where n≧3; and
an ith land in an ith layer, of third and later layers, from the through hole via side is larger in external size than an (i−1)th land in an (i−1)th layer from the through hole via side in the planar view, where 3≦i≦n.

5. The semiconductor device according to claim 1, wherein the first land in the first layer from the through hole via side to a land under the semiconductor substrate at a depth corresponding to a radius of the through hole via, of the group of lands, have gradually increasing external sizes.

6. An electronic device comprising:
a semiconductor device including:
a semiconductor substrate;
a through hole via which pierces the semiconductor substrate; and
multilayer wirings disposed under the semiconductor substrate and including plural layers of a group of lands disposed under the through hole via,
the group of lands including:
a first land in a first layer from a through hole via side which is disposed on an under surface of the through hole via and which is equal in external size to or smaller in external size than the through hole via in planar view; and
a second land in a second layer from the through hole via side which is disposed under the first land and which is larger in external size than the first land in the planar view; and
a board stacked together with the semiconductor device and electrically connected to the multilayer wirings.
